(19) United States
(12) Patent Application Publication
(10) Pub. No.: US 2014/0224964 A1
(43) Pub. Date: Aug. 14, 2014

(54) APPARATUS AND METHOD FOR DETECTION OF RADIATION

(71) Applicant: IMAGE INSIGHT INC., East Hartford, CT (US)

(72) Inventors: Peter R. SOLOMON, West Hartford, CT (US); Gordon A. DRUKIER, New Haven, CT (US); Eric P. RUBENSTEIN, Longmeadow, CT (US); Gregory Nicholas BENES, Lincoln, MA (US)

(21) Appl. No.: 14/176,531

(22) Filed: Feb. 10, 2014

Related U.S. Application Data
(60) Provisional application No. 61/762,772, filed on Feb. 8, 2013.

(51) Int. Cl. G01T 7/12; G01T 1/00; H01L 27/146

(52) U.S. Cl. CPC G01T 7/12; H01L 27/146; G01T 1/00
USPC 250/208.1

(57) ABSTRACT

Systems and methods for identifying pixels in digital images and video images that have interacted with high energy particles are described herein and using this system to coordination imagers and network alerts to permit the system to separate non-radioactive objects from radioactive objects.

### CROSS-REFERENCE TO RELATED APPLICATION

This application claims the priority benefit of U.S. Provisional Patent Application No. 61/762,772, filed Feb. 8, 2013 entitled “APPARATUS AND METHOD FOR DETECTION OF RADIATION,” which is incorporated herein by reference in its entirety.

### BACKGROUND

The public, the military and first responders can be exposed to excess radioactivity due to accidents such as the nuclear reactor destruction in Fukushima, Japan or due to acts of terrorism by a Dirty Bomb, Radiation Exposure Device or nuclear device. The ability to detect and appropriately react to mitigate the damage from exposure to radioactive materials would be facilitated by a large-scale, wide spread network of radiation sensors which report radioactivity measurements to a first responder command center and which can be positioned and operated by the command center. However, the installation of such a network of radiation sensors would be costly and delay the readiness of the system.

Radiation sensing networks are being developed in Europe in case of a nuclear power-plant accident. For example, the Real-time On-line Decision Support (RODOS) system for off-site emergency management in Europe is being planned to provide consistent and comprehensive information on present and future radiological situations, the extent, benefits and drawbacks of emergency actions and countermeasures, and methodological support for making decisions on emergency response strategies. RODOS includes geographical, meteorological and radiation propagation detection modules; it also serves as a data accumulation point for radiological and atmospheric monitoring networks. Radiation sensing data provided by networked detectors would complement and enrich the radiation database like RODOS available to security authorities and disaster recovery agencies.

The ability to detect and respond to the unauthorized transportation, accidental release or terrorist release of radioactive materials over a wide area is pressing due to the break-up of countries having nuclear weapons and nuclear reactors. Radioisotope smuggling and black market sales of radioactive material has increased substantially in the recent past. A General Accounting Office report documents some of the International Atomic Energy Agency's (IAEA) 181 confirmed cases of illegal sales of nuclear material since 1992. Twenty of these incidents involved the transfer or attempted transfer of nuclear weapons useable material, namely Pu-239 and 20%-90% Highly Enriched Uranium (HEU). Although the most ominous risk from rogue radiological material is related to HEU's use in the construction of a nuclear bomb, HEU could also be used as the raw material for a Dirty Bomb or Radiation Exposure Device. Indeed, any radioisotope can be used in the construction of a Dirty Bomb or Radiation Exposure Device. However, some radioisotopes, for example Cs-137, Sr-90, or Co-60 are more dangerous than others for this application. For example, U-235, due to its comparatively low level of gamma ray activity, is not nearly as dangerous as a comparable mass of Co-60. Dirty bombs would be economically devastating to a region due to the high expense for decontamination, clean up, and economic loss should one be detonated.

Radioactive material dispersed via the detonation of a conventional explosive as in a dirty bomb or dispersed mechanically as in a radiation exposure device would be economically devastating to the region affected. Access to non-weapons-usable nuclear material is typically easier than to HEU or Pu-239, magnifying the dirty bomb threat arising from non-weapons-usable materials. This threat is heightened by the fact that nuclear contraband is typically smuggled in quantities that rarely exceed one kilogram and that nearly all of the smuggling cases were detected due to police investigations. The clean-up costs from even this small amount of radioactive material could be tremendous. It is better to detect the illegal transport of radiological materials and interdict it at an early stage.

### SUMMARY OF THE INVENTION

Embodiments include a system including at least one imager having a pixelated chip that is capable of relaying information regarding the interaction of the high energy particle with the pixel while simultaneously obtaining an image, a central command center with a processor for receiving and interpreting said information from the imager, and for issuing operating instructions to remotely control the imager, and means for communication between the imager and the central command center. The system may also include at least one processor that is in communication with the imager, which is able to determine that a pixel or pixels have interacted with one or more high energy particle.

In some embodiments, the imagers may be standard unmodified imagers or cameras, including surveillance cameras, smartphone or tablet cameras, and webcams. These devices may be capable of relaying to the central command center and the command center may be capable of relaying information and instructions back to the imager. For example, the imager may send information relating to the location of imager when an image is captured, the time of image capture, GPS coordinates of the device during image capture, and the like and combinations thereof. Secure communication between the device and central command center can be supported using standard protocols over cell networks, the internet and available wifi networks. The data collected by the imagers can be saved at the central command center using, for example, a secure central server, and in some embodiments, the image data can be viewed at the central command, location or GPS data can be displayed on digital maps, potential radioactive interactions captured on the image data can be analyzed by the central command center's processor and the data can be displayed on graphs or tables, and the like an combinations thereof. In particular, embodiments, the command center processor may be capable of analyzing the data from multiple devices simultaneously. For example, the command center may use image and location data from multiple imagers at different locations, identify potential high energy particle interactions on each of the images collected from multiple imagers, and compile this data to identify hot zones where the likelihood of a radioactive source being present is high and safe zones where the likelihood of a radioactive source is being present is low. In some embodiments, the command center may use this data and the product of analysis to set cordons and vector personnel to an affected area. In certain embodiments, the command center may triangulate the likely position of a radioactive source by compiling the data from multiple imagers and analyzing this data as discussed above. In some embodiments, the central command center may be capable of using the readings from many devices in a given location to determine radioactivity readings that would be too low for a single device to accurately determine in the same time period.

In some embodiments, the command center may be capable of issuing operating instructions to the one or more imager. For example, the command center may send instructions to one or more imagers to acquire additional image data without user action. In certain embodiments, the command center may send instructions to the imager to analyze one or more images before, during, or after image acquisition. In some embodiments, the instructions may activate operating instructions installed on the imager. For example, a computer program or application (i.e., “app”) may be installed on the imager or a processor associated with the imager, and a portion of these instructions may cause the imager to acquire images, analyze user images, or send additional images, location, or other data to the command center without user action when instructions are received from the command center. In other embodiments, the command center may send a computer program or application that was not previously installed on the imager or processor associated with the imager that installs itself, and once the program is installed, the program may cause the imager to acquire images, analyze user images, or send additional images, location, or other data to the command center without user action.

In various embodiments, the instructions sent to devices from the command center may cause one or more of the imagers in communication with the command center to: acquire image data, take radioactivity readings, acquire image data or take radioactivity readings for a particular duration of time or at time points, for example, every 1 second, 5 seconds, 10 seconds, 20 seconds, 30 seconds, 1 minute, 5 minutes, and the like, identify potential interactions with high energy particles on the pixilated chip, initiate dose measurements, initiate alarm functions, display instructions to the imager user, communicate to a command center to allow it to perform all of the functions of the central command center; give control of the device to a command center user, and the like and various combinations thereof.

In various embodiments, such instructions may sent to an individual device, a subset or group of devices in communication with the command center, or all of the devices in communication with the command center. For example, in some embodiments, such instructions may be sent to a single device that has acquired image data indicating that a high energy particle has interacted with the pixilated chip. In other embodiments, instructions may be sent to all imagers in communication with the command center within a particular geographic radius, and in still other embodiments, such instructions may be sent sequentially. For example, instructions may be issued to an individual device that has received a potential interaction with a high energy particle that cause the device to acquire additional data verifying the high energy particle interaction, and once the interaction has been verified, the command center may send instructions to all devices in the area surrounding the high energy particle interaction, and so on. In embodiments, in which the command center causes the imager to display instructions to the user, the instructions may be, for example: “Acquire image data from an area,” “Proceed through inner cordon to ensure all civilian personnel are clear, then withdraw to safe zone,” “All non-essential responders should withdraw beyond outer cordon,” and in some embodiments, instructions can be issued to the public to evacuate certain areas.

In some embodiments, the command center may be capable of issuing instructions to the device to cause it to show a false reading of elevated radioactivity level for training the users of the device. The training exercise could require users to find the location where the simulated radioactivity reading is the highest. The same function could be used as a game for consumers with rewards for finding the hot spot as a means of encouraging the use of the app and hence acquiring a high volume of real readings from these users.

### DESCRIPTION OF DRAWINGS

FIG. 1 schematically illustrates a system including imagers, processors, and a control or command center and a mobile command center that can be used to identify high energy particles emitted from a source of radioactive material.

FIG. 2 shoes the pixel coordinates of gamma-ray strikes on the CCD of a test bed digital video camera. The data are summed over 15 seconds of video and represent almost two gamma-ray hits per second with only 16 μC of radioactivity, located 1.5 cm from the CCD detector.

FIG. 3A shows an astronomical image from a CCD detector before analysis and identification of high energy particles in the image; FIG. 3B illustrates the identification of signals due to high energy particles interacting with the pixels.

FIG. 4 shows the signal that would be expected to be measured for a moving source of radiation as measured using versions of the apparatus and methods disclosed.

FIG. 5A-B are cartoons illustrating how two separate detectors can be used to separate radiation producing or high energy particle emitting objects from other objects which are not producing or carrying harmful radioactive material.

FIG. 6 shows the acquisition and analysis of images from one or more imagers capable of detecting high energy particles emitted from nuclear decay of radioactive materials according to an embodiment.

FIG. 7 is a flow diagram for the acquisition and analysis of images from one or more imagers capable of detecting high energy particles emitted from nuclear decay of radioactive materials according to an embodiment.

FIG. 8 is a flow diagram illustrating a routine for acquiring and processing images from a pixilated imager to locate evidence of gamma rays emitted by a material according to an embodiment.

FIG. 9 is a flow diagram illustrating a routine for acquiring and analyzing images from a pixilated imager to locate evidence of gamma rays emitted by a material according to an embodiment.

FIG. 10A-D are illustrations depicting control experiments performed using a Logitech webcam, a CCD based device, collecting 15 seconds of video at 15 frames/s. FIG. 10A refers to “Control-1”, FIG. 10B refers to “Control-2”, FIG. 10C refers to “Control-3” and FIG. 10D refers to “Control-4”.

FIG. 11A-C are the results from experiments performed with 16 μC's of radioactive source material, as described in Table 1 and Table 2.

FIG. 12 is a flow diagram for the acquisition and analysis of images from a pixilated detector capable of detecting high energy particles emitted from nuclear decay of radioactive materials.

FIG. 13 is a flow diagram illustrating a routine for analyzing images from a pixilated imager to locate evidence of gamma rays emitted by a material.

FIG. 14A is images from a detector without gamma ray detections, and FIG. 14B is an image with gamma ray detections as white flecks (inside white circles).

### DETAILED DESCRIPTION

Before the present compositions and methods are described, it is to be understood that this invention is not limited to the particular compositions, methodologies or protocols described, as these may vary. It is also to be understood that the terminology used in the description is for the purpose of describing the particular versions or embodiments only, and is not intended to limit the scope of the present compositions and methods which will be limited only by the appended claims.

It must also be noted that as used herein and in the appended claims, the singular forms “a,” “an,” and “the” include plural reference unless the context clearly dictates otherwise. Thus, for example, reference to a “gamma ray” is a reference to one or more gamma rays and equivalents thereof known to those skilled in the art, and so forth. Unless defined otherwise, all technical and scientific terms used herein have the same meanings as commonly understood by one of ordinary skill in the art. Although any methods and materials similar or equivalent to those described herein can be used in the practice or testing of embodiments of the present invention, the preferred methods, devices, and materials are now described. All publications mentioned herein are incorporated by reference. Nothing herein is to be construed as an admission that the invention is not entitled to antedate such disclosure by virtue of prior invention.

“Optional” or “optionally” means that the subsequently described event or circumstance may or may not occur, and that the description includes instances where the event occurs and instances where it does not.

Embodiments are directed to systems and methods for using a central controller or central command to coordinate activity among existing image detectors to identify and track emissions from radioactive materials. Processors associated with the image detectors are in communication with processors associated with the central controller or central command and are capable of signaling the central controller or central command when radiation is detected. The central command processors may transmit signals or instructions to the image detector processors that allow for acquisition and processing of data such as radiation levels and dose data, transmit signals to other processors and imagers, to other devices such as cellular telephones, tablets, computers, and the like, and various combinations thereof to acquire data and/or alert first responders and other users of that radiation has been detected.

For ease of understanding, it will be understood that image detectors either include or are in communication with a processor. Similarly, it will be understood that the control or command center includes one or more processors. Therefore, reference of, for example, communication between an imager and a control or command center means that processors associated with the image detector and control or command center are in communication with one another.

The image detectors of various embodiments, may include any image detectors including pixilated chips. Such image detectors may include charge-coupled (CCD) devices and complementary metal oxide semiconductor (CMOS) devices, that use a light-sensitive pixilated chip containing semiconductor material to create digital still and video images from ambient light. Such imagers are well known, and use of such image detectors is widespread and common throughout the world in, for example, still or video cameras, cellular phones, webcams, netcams, security cameras, traffic cameras, and the like.

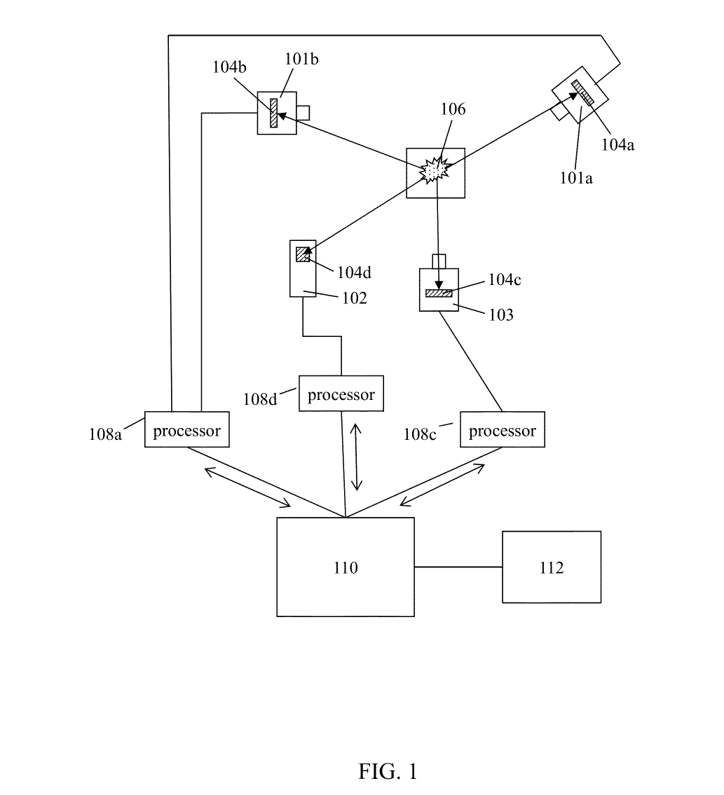

FIG. 1 provides a schematic of a system of some embodiments that includes one or more image detectors 101a, 101b, 102, 103, including pixilated chips 104a, 104b, 104c, 104d that are configured to interact with ambient light and transmit image data to a processor 108a, 108b, 108c having one or more processing units configured to create and output digital video or digital images from the data collected by the pixilated chips 104a, 104b, 104c, 104d. In some embodiments, the processor 108a may be an external computer that can collect image data from one or more image detectors 101a, 101b, and in some embodiments, such image detectors 101a, 101b may be networked. For example, the imager detectors 101a, 101b may be part of a network security cameras or traffic cameras. In other embodiments, the processor 108b, 108c may be integrated into a device having an image detector such as a cellular telephone 102 or a hand held camera 103. In these various embodiments, the processor 108a, 108b, 108c may include one or more processing units that are configured to run a program or “app” that detects pixels in the pixelated chips 104a, 104b, 104c, 104d of image detectors 101a, 101b, 102, 103 that have been contacted by a high energy particle.

In use, the one or more image detectors 101a, 101b, 102, 103 may be positioned to collect image data from ambient light. When a source of radioactive material 106 is nearby high energy particles (indicated by arrows) emitted from the source of radioactive material 106 may contact the pixilated chips 104a, 104b, 104c, 104d of the image detectors 101a, 101b, 102, 103. The pixel contacted may produce a charge that is higher than the charge produced as the result of contact with a photon from ambient light producing a high rate count pixel and a “bright spot” on the image that may be undetectable by the human eye. One or more processing units of the processor may be configured to run a program, i.e., carry out instructions, that identify pixels that have interacted with a high energy particle.

In some embodiments, the processors 108a, 108b, 108c may be in communication with a control or command center 110. The control or command center 110 can include any number of processors, each processor having one or more processing unit and may be capable of receiving and transmitting data and instructions to the processors 108a, 108b, 108c. For example, in some embodiments, the control or command center 110 may receive a signal from a processor 108a, 108b, 108c that a pixel of the pixilated chip 104a, 104b, 104c, 104d of one or more associated image detector 101a, 101b, 102, 103 has interacted with a high energy particle. In response, the control or command center 110 may transmit a signal to the processor 108a, 108b, 108c that causes the processor 108a, 108b, 108c to collect more data from the image detector 101a, 101b, 102, 103 that includes the pixel that has been indicated as having interacted with the high energy particle. The central command center 110 may also transmit other instructions to acquire dose measurements or other radioactivity measurements of specified duration and periodicity.

In other embodiments, the control or command center 110 may receive a signal from one or more processor 108a, 108b, 108c indicating that a high energy particle has been detected, and the control or command center 110 may cause processors 108a, 108b, 108c to collect additional data from imagers that have interacted with the high energy particle as well as imagers that have not been indicated to have interacted with a high energy particle.

In still other embodiments, the control or command center 110 may activate additional processors and image detectors to collect data to identify pixels that have interacted with high energy particles. For example, in some embodiments, the control or command center 110 may activate processors and image detectors in an area surrounding detection of a high energy particle to determine how far the radiation has spread from the source or to track a source or potential source of radioactive material moving through an area. Or, in other embodiments, the control or command center 110 may acquire image data from processors and image detectors in an area surrounding detection that have not detected high energy particles. In still further embodiments, the control or command center 110 may activate processors and image detectors or acquire image data from processors and image detectors that have not detected radiation in the absence of an alert signal to perform, for example, random sweeps of an area or for maintenance purposes, or for calibration purposes, or for the purpose of carrying out a scientific investigation of background or cosmic ray radiation.

The control or command center 110 may further include one or more user interfaces, alert systems, or combinations thereof that allow information regarding the presence or potential presence of high energy particle to be transmitted to a user. For example, in some embodiments, the system may include one or more video monitors that produce a signal such as, for example, an icon on a screen, indicated that high energy particles have been detected, and in certain embodiments, the icon may be produced on a map and may show the geographical location of the detected high energy particle. In particular embodiments, the control or command center 110 may collect image data from processors that have communicated the presence of a high energy particle and display the images on a monitor. The user may use these images to identify potential sources of the radioactive material and/or to evaluate the potential threat. For example, the presence of a large number of people may cause the user to initiate an evacuation procedure and/or alert local authorities to the potential threat.

In other embodiments, an audible alert may be produced at or by the control or command center 110, or an audible alert may be sent to another device such as a computer, cellular telephone, radio, CB, or other device to alert one or more users of the detected high energy particles. In further embodiments, the alert may be geographically coordinated to alert first responders and other users in a particular area having a high likelihood of being impacted by the source of radioactivity.

The processors of the control or command center 110 and the processors 108a, 108b, 108c associated with the image detectors 101a, 101b, 102, 103 may exchange various types of data. For example, in some embodiments, the processors 108a, 108b, 108c may stream image data to the control or command center 110 where it may be further processed. In other embodiments, the processors 108a, 108b, 108c may transmit an alert, identification number, GPS coordinates, or other non-image data that is received by the control or command center 110, and the control or command center can use this data to respond to the detected high energy particle. Thus, the signal generated by the image detector processors 108a, 108b, 108c may or may not contain image data.

Similarly, the control or command center 110 may transmit various signals to the processors 108a, 108b, 108c. For example, in some embodiments, the control or command center 110 may transmit a signal that causes the processor to initiate a protocol that allows for further image data acquisition. Such a signal may cause the processor to carry out programming instructions included in a program specifically designed to detect radiation, or the signal may cause the processor to activate a separate program or “app” not associated with radiation detection. In other embodiments, the control or command center 110 may transmit additional programming instructions that cause the processor to carry out a protocol that was not previously incorporated into a radiation detection or non-radiation detection program on the processor. The ability to incorporate new instructions into an existing program may allow, for example, for a new set of protocols, or even a new code base, to be transmitted as part of the control or command center message that can create a whole new activity such as scanning for seismic activity to determine if a bomb has gone off. In still further embodiments, the control or command center 110 may transmit instructions to devices that were not previously in communication with the control and command center. For example, in the event of an emergency, the control and command center may transmit instructions sufficient to allow all cellular telephones or networked cameras in an area code to detect high energy particles.

The various components of the system may be in communication with one another by any means. For example, in some embodiments, the command center 110 and associated processors, image detector processors 108a, 108b, 108c, and image detectors 101a, 101b, 102, 103 may communicate via the internet and the internet communication can be facilitated by wireless, wifi, connections, Ethernet connections, Bluetooth, LAN, Wi-Max, Disruption-Tolerant Networking protocols, Delay-Tolerant Networking protocols or combinations thereof. In other embodiments, the system or portions of the system may be interconnected using wired data transfer connections such as USB, RCA, optical fiber, coaxial, telephone, and the like and combinations thereof.

In some embodiments, the control or command center 110 may be located at a fixed location. For example, a control or command center 110 that is in communication with image detectors associated with a surveillance or security system of a building may be located at a particular location in a building or a control or command center 110 in communication with image detectors located throughout a city may be located at, for example, a police or fire station. In other embodiments, a control or command center 110 may be mobile. For example, a laptop or tablet may be used as a control or command center 110 or a more complex control or command center 110 may be built into a vehicle such as a car, truck, van, or airplane. In other embodiments, a mobile command center 112 may operate through and be in communication with the central command center 110.

In certain embodiments, the processor associated with the image detectors 108a, 108b, 108c (i.e., a first processor) may include a processor readable storage medium containing various instructions that can be carried out continually or initiated by a user. For example, in some embodiments, a processor associated with an imager may include a processor readable storage medium containing instructions for scanning image data from the one or more image detectors, and identifying each pixelated chip having one or more pixels that have interacted with a high energy particle. The step of identifying can result in real time detection of high energy particles. In the event that no pixels that have interacted with high energy particles are identified, further instructions may include an instruction to repeat the instruction for scanning. Thus, image detectors that are in constant use such as surveillance and security cameras can continually scan all data acquired. In the event a pixel that has interacted with a high energy particle is identified, additional instructions for generating an alert signal in response to the one or more pixels that have interacted with a high energy particle, and transmitting the alert signal to a second processor associated with the control or command center 110 may be carried out.

In other embodiments, a user may initiate scanning by activating a mechanical button or graphical button included on a graphical user interface. Such user initiated scanning may be carried out for a particular period of time, for example, during use of a handheld, cellular telephone, or webcam camera, or a time period applied to the activation, for example, image data may be acquired for several seconds or minutes upon user initiation. In another example, the scanning may be carried out repeatedly after a specific waiting period or after a randomly determined waiting period has elapsed. After scanning, the processor may carry out instructions for identifying pixels that have interacted with high energy particles and display results on a user interface. In the event a pixel that has interacted with a high energy particle is identified, additional instructions for generating an alert signal in response to the one or more pixels that have interacted with a high energy particle, and transmitting the alert signal to a second processor associated with the control or command center 110 may be carried out. Instructions for generating an alert signal and transmitting to the control or command center can be carried out automatically, or in some embodiment, the user may initiate the step of transmitting. For example, an alert may be displayed on the user interface and the user may view output data and a button may be provided that allows the user to transmit a signal to the control or command center.

The processor readable storage medium may include any number of additional instructions that allow the first processor to, for example, identify false positives, compare various still images or frames in video images, locate a source or potential source of high energy particles. In some embodiments, such instructions can be carried out automatically or activation by a local user may initiate carrying out of these instructions.

The control or command center 110 may include any number of processors (i.e., second processors) and processor readable storage media that allow the control or command center 110 to acquire signals from various image detectors and processors associated with image detectors and transmit signals and instructions back to the processors associated with the image detectors (i.e., first processors), and the first processor may be capable of receiving signals from a second processor associated with the control or command center causing the said first processor to issue any one of its instructions to the image detectors. For example, the first processor readable storage medium may include instructions that allow the control or command center 110 to initiate any and all of the instructions on the processor readable storage medium. For example, in some embodiments, the first processor readable storage medium may include instructions for overriding user activation or repeating scanning of image data acquired from one or more imagers that are under user or local control. An alternative instruction from the control or command center would be to send the user or local device a simulated reading in order to facilitate training exercises for multiple users.

In particular embodiments, the control or command center 110 may include instructions for automatically generating a signal when radiation is detected that is over a particular threshold (i.e., a radiation event). The signal may be any type of signal including, but not limited to, an audible alarm, visual signal, or both to alert users at the control or command center 110 of radiation event, an alert signal initiating an audible alarm, visual signal, or both to alert users or other people of the radiation event via telephone, cellular telephone, internet, and the like and combinations thereof, a signal or instruction activating imagers in a geographical location surrounding the radiation event, a signal or instruction allowing the control or command center 110 to access image data on first processors, a signal or instruction causing image detectors to acquire and analyze additional image data, a signal or instruction causing processors associated with image detectors to transmit additional image data to the control or command center 110, and the like and combinations thereof. In further embodiments, the control or command center 110 may transmit a signal or instructions modifying or verifying parameters on the image detectors to allow for acquisition of specific data.

The control or command center may further include instructions for geographically mapping the signals received from various image detectors. For example, the control or command center may include instructions for generating a map of a geographical area and superimposing on this map the locations of any image detectors in the geographical area using one or more icons. In some embodiments, the control or command center 110 may include instructions for grading the radiation level in the geographical area and superimposing this information on the map. For example, icons of different color or style can be used to indicate progressively higher radiation levels. In still other embodiments, the control or command center 110 may carryout instructions for displaying images of geographical features derived from image data surrounding the radiation event such as buildings, people, vehicles, fixtures, and the like. Such images may be displayed on the same or different monitors as the map data.

In further embodiments, the control or command center 110 may analyze data acquired from multiple image detectors spread over a broad geographical area determine the average dose of radiation in a particular area and/or identify “hot zones” such as for example a geographical region having higher than normal incidence of high energy particles interacting with the pixilated chips of one or more imagers where the likelihood of a source of high energy particles may be found is high. Identifying “hot zones” may be used to manage a radiation event by alerting individuals such as first responders in or near a hot zone to take action, and setting limits to cordon off areas surrounding the radiation event allowing people near the event to be moved to a safe location. In still other embodiments, the control or command center 110 may analyze data from multiple image detectors to allow users to identify the source of the high energy particles. For example, the control or command center 110 may acquire data from fixed image detectors such as surveillance cameras and hand held devices to direct users having hand held devices to the source.

In further embodiments, the control or command center 110 may analyze data from one or more image detectors and produce graphs or charts illustrating the average radiation dose detected over time for individual image detectors or devices, a particular geographic area, or combinations thereof and display these data. Such data may exhibit data based on preset standards or based on user inputted parameters. In still other embodiments, instructions contained on individual devices may allow for local analysis and graphical or chart presentation of data collected from a single image detector or a small collection of image detectors.

In some embodiments, the instructions and methods described above may be contained on a computer program that is loaded onto a pre-existing device or loaded during manufacture of the device. Thus, each device may be capable of carrying out all functions if signaled. In other embodiments, a computer program may be loaded onto a pre-existing device or loaded during manufacture may allow the device to be accessed by the control or command center 110, and the control or command center 110 can send instructions to the device as necessary to allow for high energy particle identification and data acquisition to the control or command center 110.

Pixilated chips may be used in a variety of image detectors including but not limited to. These image detectors may be easy to use, readily available, directly digitize data, interface with computers easily, have exceptional quantum efficiency, low noise and a linear response to photon energy, high energy particles and gamma rays emitted from sources of radioactive material. When a photon, gamma ray, or high energy particle strikes a pixel in the light-sensitive pixilated chip, electrons may move into the conduction band of the material providing a charge or potential proportional to the number and energy of particles incident and transparent to the pixel. Thus, higher energy photons may produce larger numbers of counts within the affected pixels allowing the processor to determine light versus shadow and the color of the light. However in the case of a high energy particle or gamma ray, static-like bright spots usually 1, 2 or 4 pixels in size may be created on the resulting image allowing for the identification of high energy particles and potentially radioactive material. Furthermore, the brightness of the spots may depend upon the energy of the particle that strikes the pixel. As such, the type of radioactive material may also be determined using devices containing light-sensitive pixilated chips.

A “pixel” refers to a detector element unit cell for converting electromagnetic radiation to signal electrons by the photoelectric effect. The generated charge may be collected and may depend upon the number of pixels and/or the amount of charge the pixels can hold. The formation of a particular well for a pixel may depend upon the dopant and concentration and that different processing techniques may be used to tailor the doping profiles to optimize a sensing operation for a particular energy of electromagnetic radiation. Substrates for pixels may be a p-type silicon substrate, however other options may also be used, such as, p on p⁻ substrates, or p on p⁺ substrates, SOI, BiCMOS or the like. Further, other semiconductor substrates, for example, silicon-germanium, germanium, silicon-on-sapphire, and/or gallium-arsenide substrates, among many others may be used. It should be understood that pixels may be aligned in an M×N array accessed using row and column select circuitry.

Detecting radioactive material may involve sorting through environmental monitoring data for the effects of high energy particles, neutrons, or gamma rays (γ's) emitted from the spontaneous decay of fissionable isotopes. Nuclear decay may generally involve the ejection of an alpha particle (Helium nucleus) or beta particle (electron or positron) with energy in excess of one MeV (Million Electron Volts=1.6×10⁻⁶ ergs). Gamma ray photons may also be emitted from the nucleus during spontaneous decay, with energy in the range of about 10 KeV to several MeV, depending on the isotope and decay mode. The measurement of each photon's energy may be performed using a variety of detector technologies.

The method for detecting the presence of signals characteristic of photons striking the pixilated detector is composed of steps. When it is determined that a statistically significant increase in signal in an image or pixel has occurred as the result of high energy particles striking the detector (e.g. 25% above normal background), for a sufficiently long amount of time (e.g. for 3 or 4 images in a row), a “radiation event” may be taking place. A radiation event may refer to an increase in the ambient level of radiation that is deemed to be in excess of normal statistical fluctuations.

If the counts or identity of an event measured by a detector is determined to be hazardous, an alert may be initiated by communicating relevant information to a network-aware layer. Optionally, advanced command, control, coordination activities may be initiated, including a gradient search to localize the source within the camera's field of view, perform triangulation from multiple cameras, and stream alert and video to designated individuals/computers. For cameras with a fixed known position, the position of the camera may be used to approximate the location of a source or radioactive material. In addition, the position of one or more fixed cameras may be included in calculations to triangulate the location of the radioactive material.

In one embodiment, in the case of two-dimensional radiation location, a computer or processor may use the information received from one or more cameras including camera location and image data to compute radiation intensity, identify a type of material identity, compute an approximate position, or any combination of these. The location of the radiation for a small source identified may be approximated from initial images and further refined or tracked with subsequent images from the cameras. The extent of a plume of radiation may be monitored based on images and counts from the cameras. Any of several different optimization procedures may be used to optimize the position of an identified radiation source. In one embodiment, the processor may first obtain a rough estimate of the object's location by a conventional method such as triangulation. Other optimization approaches may also be used. For example, a standard technique, such as an iterative progression through trial and error to converge to the maximum, may be used. Also, a gradient search may be used to optimize the position of a source. The method may be extended to three dimensions to select a point x, y, z as the best estimate of the radioactive object's location in three dimensions.

Pixilated image detectors that can produce charge carriers in response to interaction with a photon or energetic particle may be used to provide radioactive detectors. Pixilated image detector-equipped cameras have become ubiquitous for security, transit and traffic monitoring. Non-limiting examples of such image detectors may include CCD and CMOS cameras including pre-existing security or monitoring cameras that utilized these imaging processors. These detection devices may typically be networked and monitored from an operations center and, when combined with firmware or software, may be used to determine whether one or more pixels have a charge or voltage corresponding to a high energy particle or gamma ray interaction and to detect ambient radiation and radioactive materials, the amount and type of material that is emitting high energy particles and the movement of a radioactive material that is the source of the detected high energy particles.

For example, when the detector is near (e.g., less than 100 meters for energy of about 3 MeV or less) a radioactive source a corresponding increase in the rate of gamma rays striking the pixilated image detector may result. Because the level of background radiation is low (e.g., <10 counts/second per square inch), the presence of small quantities of radioactive material may be found using pixilated imagers. The charge of a pixel in an imager may be inferred from the brightness of the pixel in the image. Alternatively, the charge or voltage from the pixel during the readout process may be used directly. The imager may then relate this information to a processor that interprets the information and sounds an alarm.

In addition to sending the images and position of the CCD or CMOS imager, the imager unit may also be configured to transmit encoded information, such as the orientation of the camera, the temperature of the location, the time and the like.

In a monitoring configuration, the system or apparatus may perform continuous sampling. The system or apparatus may acquire a digital image of the environment or an object from a digital camera or digital detector. In a fast survey configuration, the system may be configured to perform non-continuous sampling from one or more images taken on demand or at longer intervals than that described elsewhere.

The sensitivity of the imager to different high energy photons may be determined using count information and calibration data from both modeling and empirical experiments. For example, an imager may be exposed to a series or known radioactive materials, such as Co-60, U-235, Bi-214 and the like, at a known distance. The charge or brightness, frequency of counts, and ratio of intensities (charge or brightness) may be determined. This information may be used to calculate the energies of gamma rays detected by the imager.

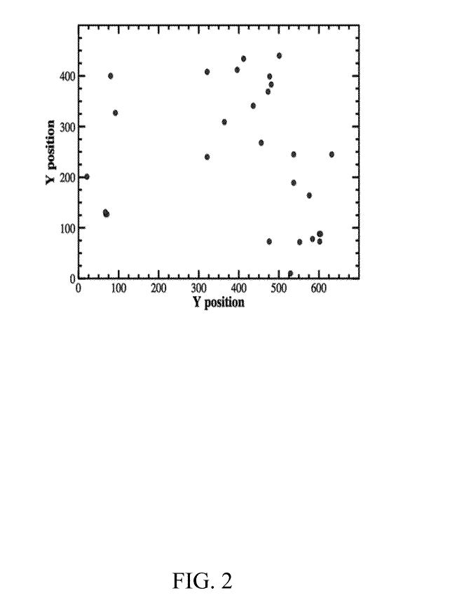

Simulations using the “MCNP” software package developed by the Diagnostics Applications Group of Los Alamos National Lab (Los Alamos National Laboratory Report, LA-10363-MS (1995)) may be used to show that the detectors and system described can provide statistically significant detections of a wide range of radioactive species. Experimental results confirming the utility of this model are illustrated in successfully detected Cobalt-60 and Cesium-137 using 1-10 μC samples as shown in FIG. 2.

Gamma rays may be emitted by radioisotopes at specific energies that are characteristic of the emitting nucleus' internal structure. A gamma ray detector able to determine the energy of individual photons may, therefore, unambiguously identify the type of nucleus that emitted the radiation. This type of spectroscopy is similar to optical spectroscopy in that the detection and identification of just a few features is sufficient to characterize the source of radiation. Whereas optical spectroscopy may often be photon starved and require the collection of numerous photons at each discrete wavelength, gamma rays have so much energy individually, that each gamma ray photon that interacts with a pixilated image detector may lead to a statistically significant data feature. The unique energy spectrum of gamma rays emitted from a radioactive material may be used to differentiate false detection from real detection.

An energy spectrum for gamma rays striking pixels in an imager may be obtained from an analysis of the image. Radioisotope identification via gamma-ray spectroscopy may involve reference library look-ups, comparisons, and decomposing a gamma spectrum into spectra from individual isotopes. The type of comparison may include the cross-correlation technique, which is a technique often used for comparing spectra having multiple lines; a variety of matching algorithms for spectral and time-series applications; Principal Component Analysis; combinations of these; or combinations that include any of these. Therefore, analysis software may be developed that measures this brightness of the spot, determines the energy spectrum of the particle and compares this information to a library spectra to allow the identification of the particular radioisotopes emitting high energy particles. The software may be used to distinguish gamma rays emitted, for example, by Co-60, as compared to Cs-137. Subsequent images may be analyzed as needed to confirm the results of the identification, or the counts or identity of the material obtained from one imager may be compared to other nearby detectors to confirm the results of the first detector. If the energy spectrum from multiple detected gamma rays matches a harmful material a warning may be issued.

More specifically, an estimate of the statistical significance of each individual gamma ray photon may be obtained by comparing its interaction with the detector with the effect that a single optical photon has on the detector. The number of electrons counted per photon may depend on both the energy of the incident photon and the instrument's gain, typically expressed as electrons per ADU (analog/digital unit). A blue-light photon having 4 eV of energy will produce, on average, 3.1 photo-electrons in a particular pixel for a Kodak KAF-1001E CCD (a particular model CCD used in high-end digital image applications). An initial estimate may be that a 200 KeV gamma ray would yield 3.1 e-/ADU*200,000 eV/4 eV=165,000 photo-electrons. However, only a portion of the gamma ray's energy may be transferred to the pixilated chip. The MCNP model simulations may suggest that the transfer of energy is significant. For example, a 766 KeV photon produced in a U-238 decay will produce ˜500 photoelectrons (“counts”) while a 1.001 MeV γ-ray will produce ˜2000 counts. These numbers may be a lower limit of counts for detecting a gamma ray as they include energy deposition in the silicon part of the upper area of the pixilated chip. It is likely that the metal leads, SiO₂ covering, doping impurities or other factors may modify or enhance the transfer of energy into the pixilated chip. These counts may permit firmware or software to be used to identify the one or more pixel locations at which the high energy gamma ray was deposited based on the number of counts over a threshold. The total counts or the number of photoelectrons produced by a gamma ray, or a value proportional to this, may be based on the charge or voltage produced by the one or more pixels in the detector due to the gamma ray.

When analyzing materials which potentially emit detectable energetic particles from one or more radioactive sources, the system and methods may be used to analyze or estimate the level of radioactive sources in the material based on the amount of signal received from the CCD or CMOS detectors. Variations in the amount and type of radioactive sources, shielding, the amounts and types of material in which the emitters are present or dispersed in, the geometric distribution of emitters in a sample, versions of the system and detectors may be used to characterize these features of the source.

Simulations using the “MCNP” software package for the expected count rate arising from various shielded radioisotopes were performed and it was determined that a CCD detector may be used to monitor a large variety of radioactive materials. Contributions to source shielding are possible, and the simulations included: 1 mm lead shielding, self-attenuation within the radioactive source, two sheets of ⅛″ thick steel, to represent a vehicle or a container's body panels, and a sheet of plate glass (conservative estimate of detector window) and a variable distance air-gap. The gamma ray intensity may depend upon material, type and amount, distance, geometry and shielding. Even when the absolute number of gamma rays detected is low, the individual gamma rays may achieve very high significance because of their high energy and the spectral signature of those gamma rays unique to the isotope.

It is reasonable to expect that the lower limit of precision for determining the energy of a gamma ray that interacts with the imager would be the Signal-to-Noise Ratio (SNR) of the counts for individual detections. This precision may be approximately equal to the square-root of the counts associated with individual gamma ray hits on the light-sensitive chip. The energy precision may be written as the uncertainty in energy (ΔE) divided by the Energy (E), or ΔE/E. For strictly Poisson statistics,

ΔE/E≈(#counts)^{1/2}/(# counts)=1/(#counts)^{1/2}

Noise may typically result from three sources: read-out electronics, dark current, and statistical uncertainty of the source counts themselves (shot-noise). Read-out noise may be predominantly determined by the quality of the electronics. Modern pixilated image detectors and controllers typically have a very low level of noise.

Dark current may be a CCD or CMOS imager chip specific value, usually expressed as the number of electrons per pixel per second, on average, which accumulate during an “exposure” or image integration period. Dark current counts may accumulate regardless of whether light or gamma rays that are transparent to the electrodes are hitting the chip. The total of such counts may depend upon the rate and total integration time. The rate of accumulation may depend strongly on the CCD or CMOS temperature, where the rate may roughly double for each increase of 6-10° C. of the chip. The effect of dark current upon image quality, and therefore the ability to detect gamma rays with as little computational effort as possible, may be insignificant for short integration times with modern cameras in good repair. By basing the detector, for example, on a video system with a frame-rate of roughly 10 to 20 frames per second, the dark current, even when the chip is warm, may be negligible compared to the expected hundreds to thousands of counts per gamma ray. This large signal may ensure excellent counting statistics and aid in energy determination, enabling accurate identification of radioactive source despite ambient radiation in the local environment. While changes in temperature may be used to modify or detect ambient noise for a CCD or CMOS imager, unlike Ge based sensors, the CCD or CMOS detectors do not need to be cooled to detect high energy particles.

Shot-noise may generate the most significant source of noise for security cameras. Model calculations suggest that a 1 MeV photon would be expected to have an uncertainty in the energy determination of approximately 1/(2000)^{1/2}=0.022, or 2.2%. Laboratory measurements show the measured counts for a lower-energy gamma ray photon from Cesium-137 to be about 200 counts, with an implied uncertainty of ˜7% per spectroscopic feature. Since most radioisotopes that emit gamma rays have multiple energies, the unique spectral fingerprint may be preserved, even with these error estimates.

Variation in the number of gamma rays that strike the detector may be eliminated using statistical methods, and the use of more than one detector may also be used to account for these variations.

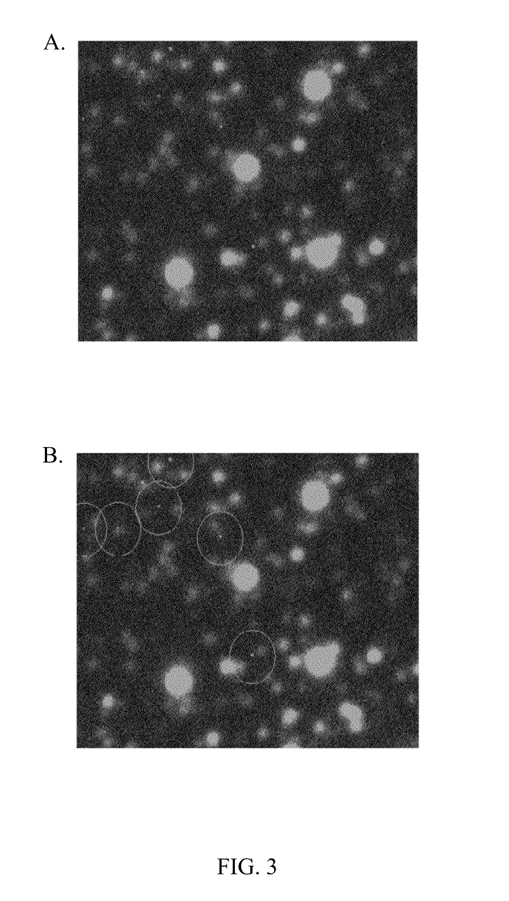

FIG. 3B illustrates that astronomical software or other similar software may be used to isolate, analyze and/or quantify detector signals which arise in digital image data from high-energy particles striking the light-sensitive chip. The small circled dots are the result of high energy gamma rays striking the detector while the large bright spots are stars that were the actual target for this image. It would be reasonable to expect that a source of radioactive material emitting high energy particles would produce images with spots similar to the small circled dots and may be used to detect, identify, and/or quantify the source of a known or unknown radioactive material.

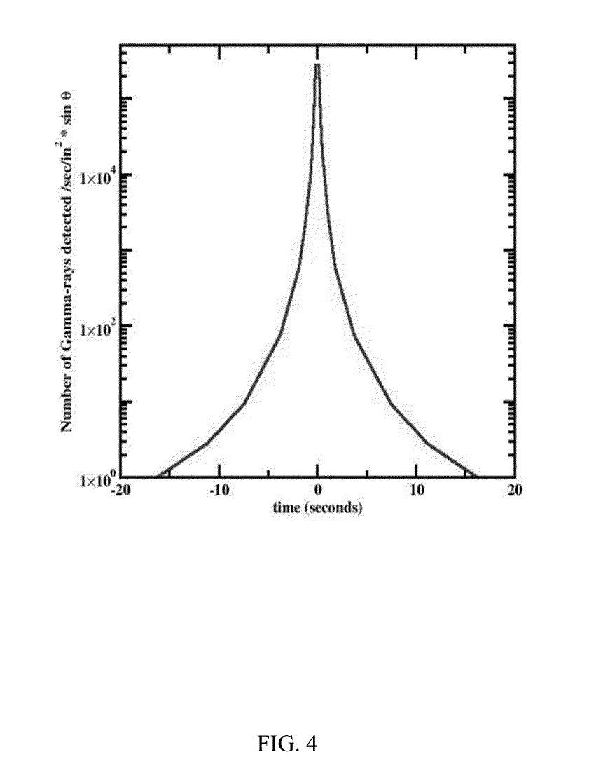

Using one or more pixel based detectors capable of detecting and characterizing energetic particles, a moving radioactive source emitting detectable energetic particles may be observed. The light-sensitive chip within the pixilated image detector may generally be in the form of a thin square. When the thin square is positioned perpendicularly to the source of the light or high energy particles, the probability of the photon or high energy particle striking a pixel within the chip may be maximized. This phenomenon is referred to as maximum flux. The probability of a photon or high energy particle striking a pixel within the chip may decrease as the source moves through the field of view of the detector. Therefore, as the source of high energy particles moves through the field of view of a static pixilated image detector (FIG. 4), the number of high energy particles striking the light-sensitive chip may increase over time as the source maintains a perpendicular position (time=0) in regard to the chip and may decrease until the source has left the detector's field of view (time=±20).

A pixilated image detector that is capable of moving may also be utilized to identify the source of photons or high energy particles. Movement of a detector, such as but not limited to, being panned, rotating along a vertical axis, and tilting, rotating along a horizontal axis, may be able to perform a gradient search, whereby the camera is rotated horizontally or vertically until maximum flux is determined. In this way, one or more pixilated image detectors may identify the location or track the movement of the photons or high energy particles source.

Buses, ferries, trains, patrol cars, or other transport vehicles are often outfitted with security cameras, which may be used to detect radioactivity. Such cameras may also serve as roving detectors. In an embodiment, the metal sides of the cameras may not be significantly thicker than that of cars.

Although the use of a single detector may provide important information about a radioactive material, even more information may be obtained when additional detectors are used together and their outputs are combined. Computer programs may be used to integrate the output from several detectors. One advantage of the disclosed system and methods may be networking detectors or cameras in close proximity to one another. Another advantage of the disclosed system and methods may be the ability to network existing detectors or cameras in close proximity to one another. Many different topologies of networks of monitoring stations may be used. For example, in one version, multiple monitoring stations may be established by using the existing security cameras. If a radioactive source were to be carried past these detectors, separate “radiation events” may be detected at each imager or camera. Trains, buses, passenger cars, people and/or animals with radiation emitting material moving near an imager may be expected to show a radiation profile. Similar scenarios may apply for people on a train platform, buses on the road, or vehicular traffic at a bridge/tunnel. Where multiple detectors are in proximity to one another, it is reasonable to expect each to have a time-series response similar in shape to that shown in FIG. 4, but having different intensities or lack of symmetry, depending on the motion, speed, and position of the source with respect to the imager.

By networking the detectors, the speed and direction of the vehicle or individual carrying a material that emits high energy particles like gamma rays from a radioactive source may be determined. Although in crowded road or urban settings it may not be possible initially to uniquely identify a vehicle or person, a carrier, in possession or transporting a radioactive material, normal traffic shear and mixing may separate the carrier of radioactive material from the other vehicles and pedestrians that are initially considered potential carriers.

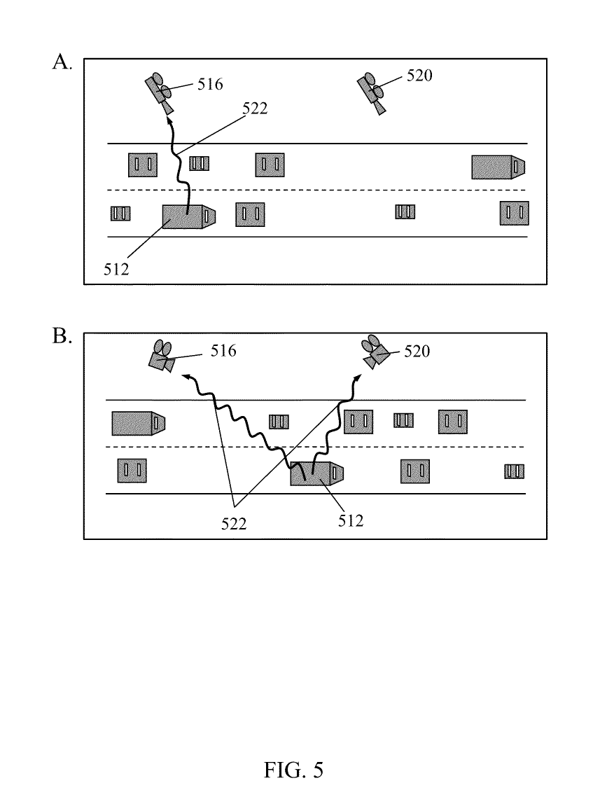

In general, there may be more than one object of interest (person, car, package, suitcase, etc.) in the field of view of the detector (FIG. 5). However, when the radioactive source has traveled or been carried to the next camera, it is likely that some of the original surrounding objects (people, cars, packages, suitcases, etc) will no longer be in close proximity to the radioactive source, as illustrated in FIG. 5A and FIG. 5B. Therefore, as radiation events are picked up by sequential cameras, the identity of the specific object containing or carrying the radioactive source may become better constrained. Sequential detections by a series of cameras may help to eliminate the innocent bystanders or vehicles from those being identified as the source of the radioactive material. These sequential detections may also serve to significantly reduce or eliminate false-positive detections.

FIG. 5A and FIG. 5B illustrates the state of the traffic at two arbitrary time periods (A) and (B). A truck 512 emitting high energy particles 522 that are detected by CCD or CMOS detector 516. Detector 520 as illustrated is not detecting high energy particles emitted by the truck source 512. The detection of high energy particles 522 by detector 516A may trigger an alert that can be used to signal detector 520 to be moved by a controller in the direction of the truck. Detector 516 may be panned in the direction of the source of the high energy particles 522 emitted by truck 512 to track the source of the high energy particles. In FIG. 5B, detectors 516 and 520 have both been moved relative to their positions in FIG. 5A, and both detector 516 and detector 520 detect high energy particles 522 emitted by moving source 512.

In a transit environment, the importance of networked cameras is likely to yield even faster, more robust identification of a source of material or an object responsible for emitting high energy photons that can be detected. For example, typical metro stations and similar facilities are designed to have at least two security cameras able to view the entire station. Simultaneous detections by these CCD or CMOS cameras may be used to provide an important corroboration on detected radiation, increase confidence in warnings or alerts issued, and aid in making tactical decisions. Moreover, since there are radiation absorbing, concrete walls in many stations, security cameras may detect the sudden “appearance” of a radioactive source. In such a situation, it may be possible to uniquely identify the individual or source responsible for the detector signal.

The pixilated image detectors used for high energy photon energy detection may contribute to a node in a network of radiation monitoring sites. Such cameras can sample their local radiation environment. Any increase in radioactivity may be identified, verified, and communicated to the relevant emergency response center or centers. The identity of the radioisotope(s) by the system and cameras may also be communicated. If a large-scale release of radioactivity occurred, whatever the cause, functioning nodes may communicate the ambient activity level, permitting the rapid mapping and forecasting of the spread of radioactive debris. The large-scale monitoring of radioactivity and alert capability may be more wide-spread as transit or other security systems are installed, such as the Federal Highway Administration's implementation of an intelligent highway system.

The pixilated image detection system may further include alert propagation and command and control protocols. Data collected by one or more detectors may be gathered and transmitted to appropriate destinations for action or storage. Multi jurisdictional concepts of operations for situations that cut across facility, local, state, and/or federal areas of responsibility may be facilitated in this manner. Common Internet protocols may be used to enable users to view video frames and updated alert data in real-time on standard PCs and wireless mobile handheld devices. These systems may be deployed ubiquitously with support for legacy infrastructure to ensure a reliable, secure and scalable platform.

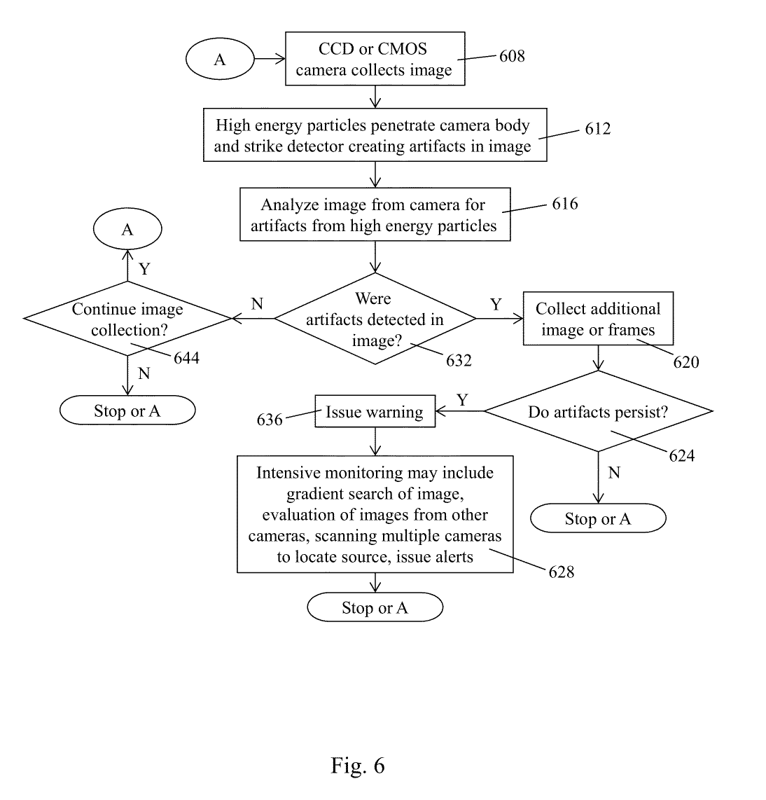

FIG. 6 is a block diagram of a method for detecting gamma radiation. In step 608, a CCD or CMOS imager collects an image of an area, volume, or combination of objects. In step 612, any high energy particles, such as gamma rays from the decay of a radioactive material, in the area imaged may strike the imager or one or more pixels in the imager creating an artifact in the image. In step 616, the image from the imager may be analyzed for artifacts from high energy particles. For example, the charge may be determined for individual pixels of the image, and/or the image may be analyzed to determine the brightness of the pixels. The image may be analyzed for objects imaged by the imager and artifacts due to gamma rays. In step 632, a determination may be made as to whether artifacts in the image from gamma rays interacting with the detector are present. If no artifacts from gamma ray interaction are detected, the routine may continue to step 644 and a determination can be made as to whether to continue image collection. If artifacts from gamma ray interaction are detected, the routine may continue with step 620 where additional images or frames of the area may be taken. In step 624, a determination can be made as to whether the artifacts persist in the image. If the artifacts do not persist, the routine may return to step 608 (labeled “A” on the diagram). If artifacts persist, a warning that gamma rays were detected may be issued. In step 628, intensive monitoring may be initiated. This may include a gradient search of images that have artifacts, evaluation of images from other cameras, scanning or panning cameras, issuing additional alerts, and/or other acts to identify the source.

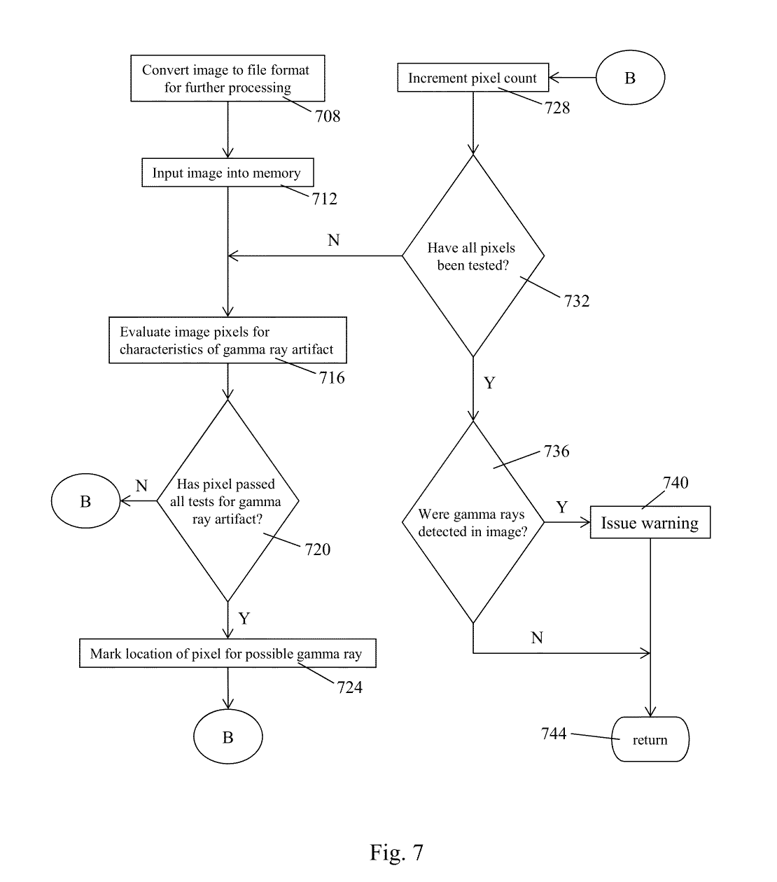

FIG. 7 refers to a method for processing images taken by a still or video imager. In step 708, an image from a camera is converted to a file format for further processing and the converted image is inputted into memory in step 712. In step 716, The image pixels are individually evaluated to identify gamma ray artifacts in the image. In step 720, a determination may be made as to whether the pixel was contacted by a gamma ray. If the pixel does not appear to have been contacted by a gamma ray, the next pixel is evaluated, and so on until all of the pixels in the image have been evaluated. If it appears that the pixel has been contacted by a gamma ray, the location of the pixel may be marked (step 724) and the pixel count may be increased (step 728), and the next pixel may then be evaluated and so on until all of the pixels in the image have been evaluated. The system can then check or verify that all of the pixels have been evaluated (step 732), and additional unevaluated pixels can be evaluated or certain pixels can be reevaluated if necessary in view of the overall results. Once all of the pixels have been evaluated, the system can determine whether any gamma rays were detected in the images (step 736). If gamma rays were detected, a warning may be issued (step 740). Otherwise, the routine may terminate or the next image may be evaluated.

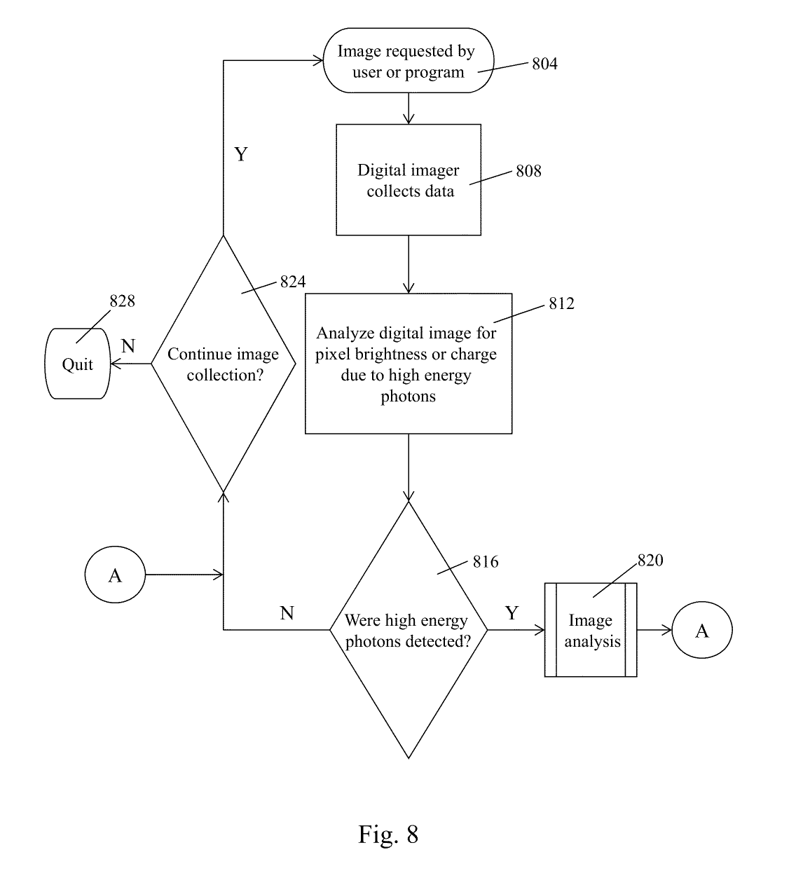

FIG. 8 describes a method for the detection of gamma rays using a CCD or CMOS imager in which a user requests an image or continuous imaging of an area 804. The imager may collect data (step 808) and analyze the image for brightness or pixel charge (step 812). A determination can be made as to whether high energy photons or gamma rays were detected in the image (step 816). If no high energy particles are detected, the system can determine whether or not to continue acquiring images or to stop the image collection. Alternatively, the system may alert the user and the user can determine whether to continue acquiring images (step 824) and image acquisition will continue until a user input is made to stop collecting data. If high energy photons or gamma rays are detected, further image analysis may be performed automatically (step 820). Once the image analysis is complete and the results returned, the system can alert the user and the user can decide whether to continue the image collection (step 824).

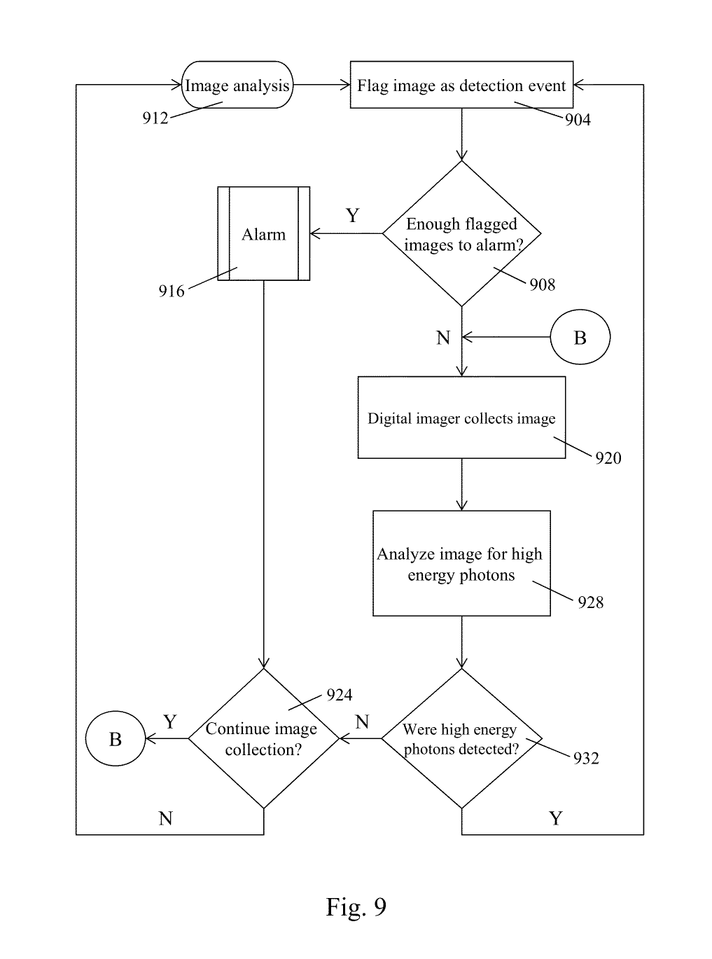

FIG. 9 describes a method for analysis of an image that includes flagging the image as one where a gamma ray detection event was detected (step 904) after image analysis which can be carried out by any method including those described in FIG. 6-8. After an image has been flagged, the system may determine whether a sufficient number of images have been flagged for detected radiation (step 908). If a sufficient number of images have been evaluated, an alarm or alert may be issued (step 916). If not, the imager may be instructed to collect an additional images (step 920) and additional analysis or additional images can be carried out (step 932). If artifacts from high energy particles are detected, the image may be flagged as a detection event (step 904) and the routine may continue. If not, a determination may then be made as to whether to continue image collection (step 924), and the routine can be stopped or return to step 904.

The image detectors of various embodiments can included in larger devices that have any number of additional features. For example, in some embodiments, such devices may include a controller that can receive information or images from the image. The controller may implement instructions, and in some embodiments, can control the movement or the position of the detector. A receiver may attached to the controller to provide input or provide a means for a user to input instructions to the controller. The receiver can include various additional features such as a keyboard, touch screen, or combination thereof for inputting user instructions, or the receiver may include features for receiving instructions from remote source by cable, radio wave, wi-fi, Bluetooth, networked computer, and the like. In certain embodiments, the receiver may include both a keyboard, touch screen, and cable, radio wave, wi-fi, bluetooth, networked computer, or various combinations thereof. In particular embodiments, the apparatuses may include a transmitter to send data, images, or instructions to another remotely located device using cables, phone lines, radio waves, Bluetooth, wi-fi, or other methods of communication.

The systems of various embodiments may include, for example, a central processing unit (CPU) having corresponding input/output ports, read-only memory (ROM) or any suitable electronic storage medium containing processor-executable instructions and calibration values, random-access memory (RAM), and a data bus of any suitable configuration. The controller of devices such as those described above may receive signals from a variety of individual pixels or from the pixilated imager or detector sensors coupled to cameras or stand alone detectors, and/or as part of a vehicle. The processing unit may be used to control the operation and/or motion of the sensors, a view taken by the sensors, and/or accept and output information to or from the sensors detectors. The controller may be connected to an input device, such as a keyboard. The controller may perform data analysis or send information from detectors to a central processing unit. Information from the sensors may be provided directly to a receiving station or through a transmitter in a known manner.

In certain embodiments, a camera phone and other portable device, for example, may be configured for remote placement and interconnection with a network of other sensors. In some embodiments, these devices may be solar powered and may be designed to connect to the network in the event that high energy particles are detected. Portions of a network of detectors may be activated to detect high energy particles when, for example, a primary detector senses high energy particles or detects a number of artifacts (i.e., high intensity pixels) that suggest that a radioactive source is in the area. The activated network may then monitor the movement of the radioactive source material.

Although the systems and devices of various embodiments can detect any type of radioisotope, some radioisotopes are easier to detect than others. The calculations and examples in the disclosure are based on U-235, which compared to Co-60 is more difficult to detect, and serve as a guide to the applicability of radiation detection systems based on semiconductor materials where the counts produced by a photon incident on a pixel is proportional to the energy of the incident gamma ray produced by the source of radiation. Although the examples and calculations disclosed herein are based on U-235, the system, methods, and apparatus may be used for the detection of high energy photons from any radioactive material that undergoes nuclear decay. These CCD and CMOS imager devices have a linear response to the incident photon energy. While U-235 may be used as an example of a material that produces detectable high energy photons, the claims and disclosure are not limited to any particular radioactive material.

Instructions or programs, which may be in firmware (computer programs contained permanently in a hardware device (as a read-only memory)), EPROM, or software, may include various routines that identify radioisotopes according to the energy spectrum of the detected radioactivity. These programs may also include the capability to accept and analyze data from remote networked digital cameras, issue distributed alerts, and use network infrastructure to coordinate detections from multiple detectors. Versions of the system for detecting and identifying radioactive material with pixilated imagers may be used to form an inexpensive, dense network of radiation detectors. Such a detector network may supply continuous real-time detection and tracking of radioactive sources over a wide area and range of environments, such as highways, factories, cities, hospitals, other institutions, and other urban or rural locations.

For example, FIG. 3 shows a portion of a typical astronomical CCD image. The spots that result from high-energy particles, cosmic rays, ambient radioactive sources, and gamma rays striking the CCD during the exposure may be identified using an automatic identification program. This system may perform real time identification once the detection parameters are set. Due to the uniformity of CCD light detection characteristics, setting the detection parameters may only be performed once for a given type of camera. Once a prototype camera is set up, other systems using that specific type of detector may operate using the same settings or with only a short calibration check.

Instructions and routines in software or firmware may be used to determine the statistical significance of each peak pixel output compared to the ambient noise. The routines may begin with a scan through the image data, looking for very high count-rate pixels. The routines may further include comparing high count-rate pixel peaks to neighboring pixels using statistical tests. The statistical tests may include minimum thresholds, minimum ratios (peak to neighbor), use of detector and electronics characteristics, or combinations of tests including these. Statistical tests and programs may be used to provide detection probabilities with low false-positive outcomes. Additional checks and comparisons of the detector signal may be used to further suppress spurious alerts.

Potential sources of false-positive outcomes include background radiation, Cosmic Rays (CRs), sudden increases due to rain washing from the air naturally occurring decay products of Radon-222, Bismuth-214 and Lead-214, and the decay of Ra-222 itself. Background activity may usually be very low, as is the system noise, so detection of bona fide radioactive sources may be accomplished with a very high degree of statistical confidence. Data screening tests of information received from detectors and cameras may be used to minimize false-positive outcomes. These may include tests for appropriateness of detected spectra and persistence of the signal in multiple exposures. In addition, a vehicle or person carrying nuclear material may trigger one radiation event after another. Such a moving detection may clearly identify a bona fide source, and may not arise from background radiation, cosmic rays, or any other local radiation artifact. Finally, a large radiation release may yield distributed, persistent activity over the region affected.

In conclusion, a system and method for the detection and identification of radioactive isotopes may include an apparatus based on a semiconductor material that may obtain photographic or video images of objects and simultaneously detect high energy particles that interact with digital still and video camera imagers. The apparatus may use CCD and CMOS based images. These detector or imagers and other digital detectors of electro-magnetic radiation and charged particles, may, in addition to detecting light, detect energetic particles and high-energy photons emitted from radioactive isotopes. The images from the one or more CCD or CMOS imagers may be transferred to a computer using a frame grabber or imaging board connected by, for example, a cable or a PCI bus to a processor. Images may also be transferred using infrared data transfer, radio waves, or other electromagnetic waves used in communication devices. The images may be stored on a disk for retrieval and further analysis; the images may be stored in a compressed format. Image sequences may be captured at full or reduced frame rates. Image data from the imagers may be sent to acquisition equipment and then to the data processing equipment, including computers and other digital or analog data manipulation and analysis machinery. An analysis of image data transferred from the above components of the system may be used to detect the presence of radioactivity.

An analysis of the images from one imager may be compared to analyzed images from other nearby imagers to determine if a false-positive conclusion has occurred. Nearby cameras should be able to detect gamma rays detected by the first imager and the energies and ratio of energies detected should be similar and may be compared using statistical and logic-based tests to verify the persistence and/or consistency of the radioactivity measured. The location of hot spots or bright spots in an image due to gamma rays emitted from a terrestrial source of radioactive material may be used with the images of objects in the imager's field of view to locate the position of the radioactivity.

### EXAMPLES

Various aspects of embodiments disclosed will be illustrated with reference to the following non-limiting examples. The examples below are merely representative of the work that contributes to the teaching of the present invention, and the present invention is not to be restricted by the examples that follow.

### Example 1

This example illustrates the ability of an imager to detect high energy particles and illustrates the sensitivity of the detector.

The functionality and sensitivity of the various imagers to detect gamma rays (still and video) from different manufacturers were performed. In each experiment, the cameras were operated, without modifications, according to their standard directions. Exposures were alternately made with and without radioactive material near the camera body. The images taken without a nearby source served as control experiments. In general, it was expected that very few of the control experiment images should display the small pixel-scale dots caused by radiation strikes on the detector. It is also reasonable to expect some, but not necessarily all, of the images (also called frames, exposures or collectively data) to contain such artifacts.

In one series of laboratory tests, a digital video camera manufactured by Logitech, specifically, the Quickcam for Notebook Pro was used. That camera contains a 1280×960 pixel Charge-Coupled Device (CCD). In a second series of tests, an Olympus Camedia C-700 digital still camera, which contains a 1600×1200 CCD was used. Both cameras were exposed, without modifications, to small, unregulated radioactive sources. When exposed to these sources, gamma rays were successfully detected as very small, distinct white dots.

When collecting radiation sensitivity data, three radioactive sources (see Table 1): (1) 1 μC Cobalt-60, (2) 5 μC Cesium-137 and (3) 10 μC Cesium-137 were used. These sources were ordered from Spectrum Techniques, Inc. of Oak Ridge, Tenn. Spectrum Techniques provides calibrated radiation sources for experimental laboratory work. The Cobalt-60 source emits powerful 1.17 MeV and 1.33 MeV gamma rays. These energetic rays are very penetrating, with only half of such gamma rays being absorbed after traversing 11 mm of lead. Cesium-137 emits 0.66 MeV gamma rays, which are about half as penetrating as are those from Co-60. Half of Cesium-137's gamma rays penetrate 5.5 mm of lead. The fact that gamma-rays pass through significant amounts of lead shielding makes it very unlikely that radioactive sources large enough to be dangerous could be surrounded by enough shielding to avoid detection, if the system sensitivity is large enough. Preliminary results of sensitivity are discussed vide infra.

TABLE 1

| | | | | | | | Lead | | |
|---|---|---|---|---|---|---|---|---|---|
| | | Calibrated | | | | | shielding | | Count |
| | | Activity | | | | | required | | rate |
| | | Level per | | Nominal | | Beta | to block | | from |
| | | Spectrum | | Decays | Gamma-ray | decay | half of | | Quantex |
| Source | | Techniques | | per | energy | energy | the γ- | | Geiger |
| Number | Radioisotope | data sheet | | second | (keV) | (keV) | rays | | Counter |
| 1 | Cobalt-60 | 1 | μC | 37,000 | 1173.2 | 317.9 | 11 | mm | 700 μR |
| | | | | | 1332.5 | | | | |
| 2 | Cesium-137 | 5 | μC | 185,000 | 32 | 511.6 | 5.5 | mm | |
| | | | | | 661.6 | 1173.2 | | | |
| 3 | Cesium-137 | 10 | μC | 370,000 | 32 | 511.6 | 5.5 | mm | |
| | | | | | 661.6 | 1173.2 | | | |

In order to assess the ultimate sensitivity of the method, Geiger-Muller counter data were collected under as nearly identical conditions as possible to the Logitech webcam CCD data. The detector chosen was a Quartex model RD8901, manufactured by Quarta in Russia. The detector's calibration has been verified to be correct to within 10% accuracy at Brookhaven National Laboratory. The detector was positioned approximately 1.5 cm from the sources, with a 1/16th inch thick piece of acrylic plastic in between the source and detector. The plastic was used to provide nominally equivalent shielding to that of the webcam cover. Normal operation for the Quartex detector is to collect data for 31 to 33 seconds and then indicate the hourly radiation exposure level in micro-Roentgen/hour. The resulting count rate average over a 6-minute sampling period is shown in Table 1 for the Cobalt-60 sample. The other sources overloaded the detector, and no reliable count rates were obtained.

Results for system sensitivity. The Olympus camera was used just with source #1. With the 1 μC Cobalt disk lying flat against the rear side of the camera, flush against its LCD view panel, there was one (1) gamma-ray hit in one of ten 0.5 second exposures. In 44 control experiments, with no radioactive source, there was no evidence of a gamma-ray detection of the camera.

More extensive experiments with the Logitech webcam were performed than with the digital still camera. In each of the webcam experiments, data were collected for 15 seconds, at 15 frames per second, to produce movies comprised of approximately 225 frames. Control experiments were performed first with the camera surrounded by lead bricks and covered with a thick black cloth. The second series of tests were identical, except that the Cobalt-60 and the two Cesium-137 sources were placed next to the webcam. The third series of tests had the camera uncovered, aimed at the ceiling of the laboratory, with no radioactive disk nearby; the lead brick over the camera was removed, but the side bricks were still in place. The final series of tests used the same set-up as the previous series, but for the inclusion of the two Cesium-137 sources. Details concerning the first two series of tests are discussed below and summarized in Table 2.

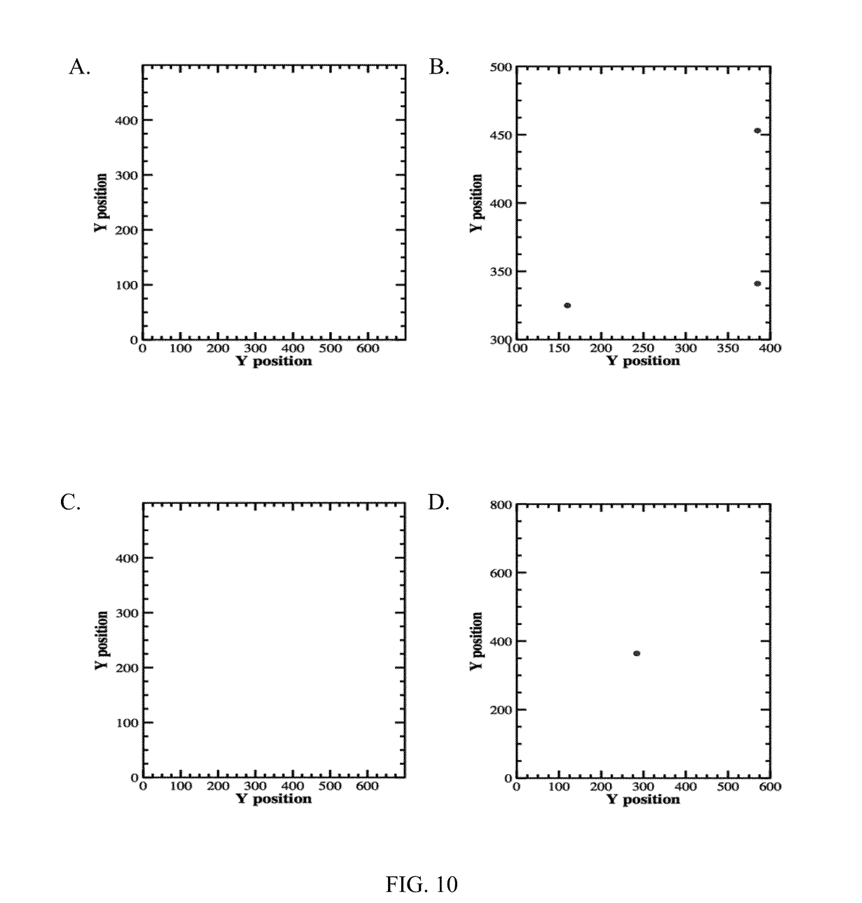

The control experiments consisted of four 15-second video clips representing 996 individual data frames, each 66.7 ms in duration. A total of four energetic particle strikes on the CCD were detected (see FIG. 10 (A-D) for pixel locations). These were presumably due to cosmic-ray impacts, or nearby radioactive decay of a naturally occurring element such as Radon or its decay products, or some other ambient source of background radiation. None of the four counts occurred closer than a few seconds to the others. This temporal gap between counts, and or a minimum count-rate, can be used as criteria to trigger an alert and also as part of a false-alarm suppression strategy.

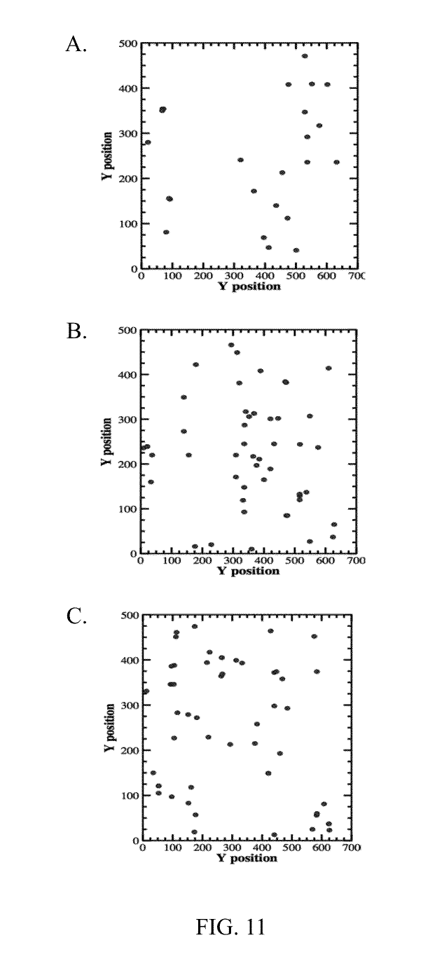

FIG. 11 (A-C) show three sequences of images taken while the webcam sat atop the three radioactive sources. The sequences were each 15 seconds long. This configuration detected 126 energetic particle strikes on the CCD among the 773 individual frames. The count rate varied between 1.6 counts/sec and 3.5 counts/sec.

An estimate of the statistical significance of these detections can be made to understand the value of the system as a warning device for radiation or for detection of ambient radioactivity. Consider separately the three “source” experiments having 24 counts (FIG. 11A), 49 counts (FIG. 11B) and 53 counts (FIG. 11C). The effective background radiation level was measured to be approximately one (1) count per 15 seconds of data in FIG. 10. Since radioactive decays follow Poisson distributions, and the number of counts per data set is greater than 20, some estimates of the significance of the detections using Gaussian statistics arguments may be made. The approximate 1-σ uncertainty in the measurements is the square-root of the measurement, or: 4.9, 7, and 7.3 counts, respectively for Source-1, Source-2, and Source-3. These values yield results of 24±4.9 counts/15-sec, 49±7 counts/15-sec, and 53±7.3 counts/15-sec. The first value is a few standard deviations away from the other two values, it is possible that the webcam may have slid slightly toward the sources after the first experiment; if so, a translation of ˜7 mm would account for the variation observed. The significance of the detections, expressed in multiples of their respective 1-δ uncertainties, is:

significance=(value−background)/uncertainty

The resulting significance of the detection of the radioactive source for the “Source-1” experiment is (24−1)/4.9=4.7σ. The corresponding values for “Source-2” and “Source-3” are 6.9σ and 7.1σ, respectively. In these experiments, it was known that there really was a radioactive source nearby, but that will not always be the case. It would be useful to know the likelihood for both false-negative and false-positive results. To determine the false-negative results, the probability that instead of recovering the expected number of counts, a number close to the background rate is found. For count rates equal to those recorded in Table 2, the probability that a statistical anomaly would produce a false-negative can be calculated by evaluating the Gaussian Probability Distribution. This can be done for a value equivalent to what would be considered normal for background, as compared to the “Total number of gamma rays detected” (called “mean value” in equation below), using the 1-σ values. This probability

$$Probability of false \text{-} negative = \frac{1}{σ \sqrt{2 π}} exp ⌊ \frac{- 1}{2} {( \frac{background value \text{-} mean value}{σ} )}^{2} ⌋$$

is:

For Source-1, this probability is about 1 in 100,000, for Source-2 and Source-3 it is more than an order of magnitude lower. The system's sensitivity therefore makes it very robust against false-negative results, i.e., if the ambient radiation is at least as intense as the very low laboratory conditions, the count rate will be high enough to make a detection. Moreover, a radioactive source will most likely be near a detector for an extended time, or else pass by multiple detectors. Therefore, the risk of missing a source is correspondingly reduced by the number of 15 second periods spent near a detector.

To calculate the false-positive probability, the same equation would be used, except the background rate and mean value definitions are reversed, and the 1-σ□ now corresponds to that of the background count rate, which is correspondingly lower. For the extremely low background rate observed, approximately 1 count per 15-seconds, the variance is ill defined from a Gaussian statistics perspective; a much longer exposure would be needed to fix it firmly. However, a rough order of magnitude estimate for the 1-σ□ uncertainty would be ±1 count (the square-root of 1). Using a value of 1 for σ means that a false-positive alert at the level of Source-1 would be a 25-σ occurrence, i.e. a formal probability <10⁻¹¹⁶. Additional analysis of the false-positive alert rate may be made with more extensive determination of the background rate and its variance. The low background rate also helps to ensure that real alerts are handled appropriately, not lost in measurement noise.

TABLE 2
LABORATORY RESULTS

| | | | Total | Number of | |
|---|---|---|---|---|---|
| | Total | # of | number | frames in | Average |
| | source | individual | of gamma- | which | counts |
| Experiment | activity | video | rays | gamma-rays | per |
| Series | (μC) | frames | detected | were detected | second |
| Control-1 | 0 | 224 | 0 | 0 | 0.0 |
| Control-2 | 0 | 224 | 3 | 3 | 0.2 |
| Control-3 | 0 | 225 | 0 | 0 | 0.0 |
| Control-4 | 0 | 224 | 1 | 1 | <0.1 |
| Source-1 | 16 | 225 | 24 | 20 | 1.6 |
| Source-2 | 16 | 223 | 49 | 36 | 3.3 |
| Source-3 | 16 | 225 | 53 | 41 | 3.5 |

Expected field sensitivity for imagers may be based upon scaling arguments using results of laboratory detections. The Federation of American Scientists performed a number of calculations to assess the likely impact of various dirty bomb scenarios. The results of their detailed investigations can be found on the FAS website (FAS Public Interest Report 55, N.2, 2002). One of these case studies considered the case of a 10,000 Curie source of Cobalt-60. Such a source is 10⁹ times more active than the 10 μCi Cesium source and 10¹⁰ times more active than the 1 μCi Cobalt source. In a preliminary calculation the source geometry or self-shielding were not changed. As distance between source and detector increases, the main effect is a fall-off of intensity that is proportional to the square of the distance between source and detector. The laboratory detections took place with a 1.5 cm distance. With the above assumptions, for a source 10¹⁰ times more active than our Cobalt-60 source, a comparable detection could be made when it is (10¹⁰)^{1/2}×1.5 cm=1500 meters away, while a source 10⁹ times more active would be detectable roughly 470 meters away. However, air-attenuation becomes important for distances greater than roughly 100 meters, at which point air becomes an important component of the shielding calculations. Since the calculated distances exceed the distance over which air-attenuation becomes important, a conservative estimate for an effective range for the detectors under these conditions would be several hundred meters, however greater ranges are possible. Alternatively, at closer separations, a stronger signal of radioactivity would be detected, or a less active source could be detected.

### Example 2

This prophetic example illustrates the use of a CCD or CMOS camera or video camera to detect gamma-rays from a radioactive material.

One or more CCD or CMOS imagers may be used to sample a region or objects in the environment to determine if radioactive materials are present. An image from each of the cameras may have the charge at each pixel determined using the imager's hardware to detect pixels with high charge caused by photoelectrons generate by gamma rays. Alternatively, the image may be analyzed using software or firmware from the camera or a central processor connected to the camera to detect gamma-ray artifacts. The data signature of a gamma ray may include one or more pixels having high charge or brightness above a background or threshold level. The charge, brightness and frequency of the pixels struck by the gamma rays emitted from a source or radioactive material is expected to be greater than the charge or brightness for the same pixels interacting with ambient light or background radiation.

Software may be used to evaluate the images from an imager and conduct a series of steps to reduce/eliminate false-positive alerts. These steps may include acquiring additional images; calibrating the detector; comparison of the image and detected high energy particles with images from other nearby cameras; comparing the counts to a threshold; comparison of the identity of the energy of the gamma rays detected with a library of known radioactive isotopes to determine if a match is possible; assembling one or more images to determine if the radioactive source is moving and if the detected high energy particles correspond to the movement of the object in the image, or any combination of these acts.

Where high energy particles above a predetermined level are detected in pixels or images from the imagers, warnings or alerts may optionally be issued to system operators or others if there is a persistent, statistically significant radiation artifact or signature in one or more pixels or images that correspond to a radioactive material.

Where high energy particles above a predetermined level and/or frequency are detected, an intensive study of the images or pixels from the cameras can be performed to more precisely locate the source or radioactive material and identify its composition. Optionally, cameras detecting gamma rays may be coordinated to triangulate the radiation source location to a small volume and to improve specificity of radioisotope identification. The location and identity of the detected radioactive source may be disseminated to system operators or others in updated alerts.

### Example 3

One non-limiting way of checking the pixels or image from an imager is to evaluate the four closest pixels (4CP) in digital image data. If the pixel or image data point under consideration is (X,Y), then the 4CP are: (X+1,Y), (X,Y+1), (X−1,Y), and (X,Y−1). The local background value of the imager can be taken as the average of the eight pixels corresponding to (X−2,Y−2), (X,Y−2), (X+2,Y−2), (X−2,Y), (X+2,Y), (X−2,Y+2), (X,Y+2), (X+2,Y+2); alternatively if a known reference object is in the field, it may be set to be the background and the average of the pixels or data points corresponding to the object set to the background.

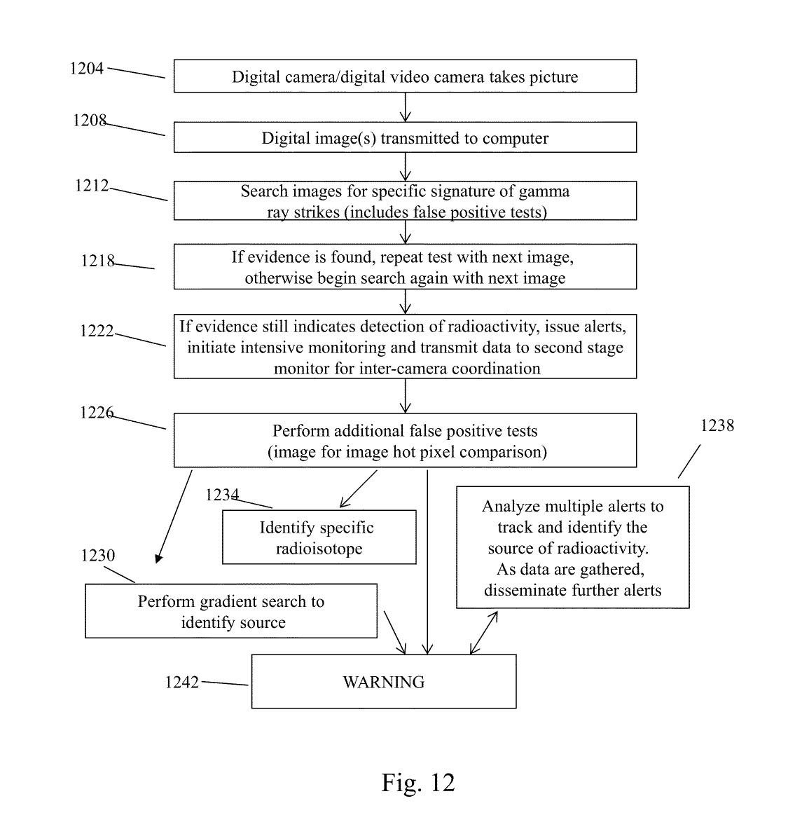

In one mode of operation as illustrated in FIG. 12, a digital camera/digital video camera takes a picture (1204) and in another step the digital image(s) may be transmitted to computer (1208). The images may be searched for specific signatures of gamma-ray strikes and may also include false positive tests (1212). If evidence of a radioactive material is found, the test may be repeated with the next available image (1218), otherwise begin again with the next image (1218). If evidence still indicates bona fide detection of radioactivity, alerts or warnings may be issued, intensive monitoring may be initiated, and data may be transmitted to a second stage monitor for inter-camera coordination 1222.

Additional false positive tests, for example image-to-image “hot pixel” comparison (1226), in which it is determined if the same pixel(s) is (are) detecting high count rates image after image. “Hot pixels,” if found to be a problem, may usually be calibrated by one of several common techniques.

Intensive monitoring may include performing a gradient search to identify source (1230), identify specific radioisotope(s) (1234), and/or issue a warning (1242). Analysis of multiple alerts enables the system and operators to track and to identify the source of radioactivity (1238).

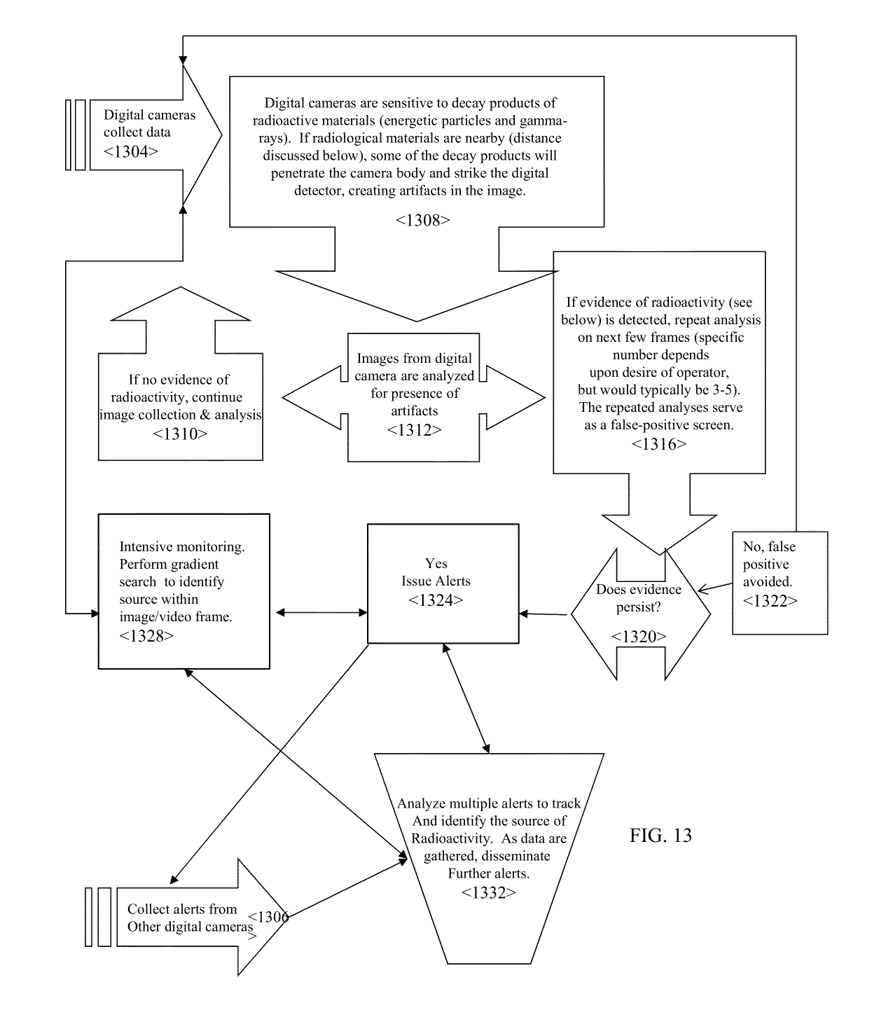

The functions of the software or firmware for interpreting the images from a digital camera or pixel data from an imager chip having one or more pixels are shown in FIG. 13. Data from the imager is collected 1304. Digital cameras are sensitive to decay products of radioactive materials (energetic particles and gamma-rays). If radiological materials are nearby, some of the decay products may penetrate the camera body and strike the digital detector, creating artifacts in the image 1308.

Images from a digital camera may be analyzed for the presence of artifacts 1312. If no evidence of radioactivity is detected, image collection may continue 1304. If evidence of radioactivity is detected, optionally repeat the analysis on one or more additional frames 1316. The repeated analyses may serve as a false-positive screen 1316. The analysis of frames may be continued until a sufficient number of frames show a radioactive material is present (evidence persists) 1320, or there is no radioactive material present (evidence for radioactive material does not persist); for example the counts, image brightness, or charge on pixels of the imager are consistently below a threshold 1320). Where the evidence does not persist, image collection may continue 1304.

If the evidence for the presence of radiation persists, an alert or warning may be issued by the system 1324. The detectors may perform intensive monitoring by a gradient search to identify a detected source, not necessarily initially within image/video frame 1328. Optionally, multiple alerts may be analyzed to track and identify the source of radioactivity. As data are gathered, further alerts may be disseminated 1332. This information may include alerts collected from other digital cameras 1306.

In FIG. 13, digital images are collected from one or more cameras/video cameras 1304. The cameras may be used for security purposes and may be networked to an operation center. These digital cameras may be used to work as radiation detectors whether or not they are utilized for video security monitoring. The detectors (e.g. CCD, CMOS, etc.) are sensitive to energetic particles from radioactive decays. Gamma rays in particular are the most likely to both reach the detector and interact with it in such a way as to be detectable. The detectors manifest this sensitivity regardless of the direction from which the gamma rays enter the camera. The physical size (e.g. in square inches) of the detector, and its angular orientation, may determine the solid angle subtended by the detector, from a radioactive source's perspective. A larger solid angle may produce a higher rate of gamma rays interacting with the detector. A radioactive source having a higher degree of activity (e.g. more decays per second) may produce a higher rate of gamma rays interacting with the detector. The data from each camera may be transmitted to a computer where the analysis is performed. The transmission may be via a cable, network, or electromagnetic radiation such as, but not limited to, radio waves. At later stages of the detection and analysis process, the results from two or more cameras may be combined to provide greater detail.

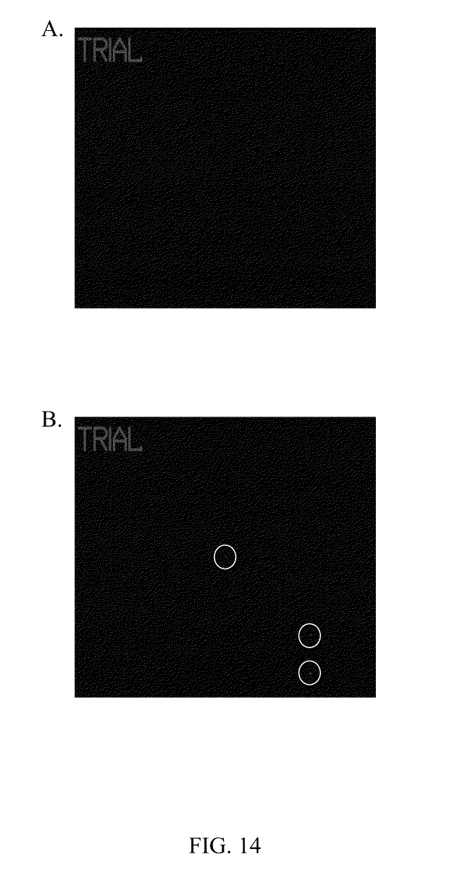

Digital cameras are sensitive to decay products of radioactive materials energetic particles and gamma-rays 1308. If radiological materials are proximate, some of the decay products will penetrate the camera body and strike the digital detector, creating artifacts in the image. In images collected from the detector, the absence of gamma rays may produce images without white flecks FIG. 14A; images or data with gamma ray detections may have white flecks FIG. 14B.

The analysis procedure 1312 may be run at specified intervals (e.g., 3 times per second), on demand (e.g., click for analysis), as fast as the camera can supply images and/or the computer or computers can analyze them, or other modes. Decisions made at steps 1324, 1328, and 1332 may influence the mode for image selection and rate.

Each image may be converted to a file format suitable for further processing (e.g. FITS, SDF etc.). Suitable programs to transfer a file into a suitable format are known in the art and include Graphic Converter by Thorsten Lemke or other similar programs. An image may be read into memory. A search may be performed on this image to look for the white flecks produced when gamma rays hit and interact with the digital detector. A combination of algorithms may be used to detect gamma ray hits in an image. The intensity of the white flecks may be used to determine the energy of the gamma ray hits, and energy ratios for the hits may also be determined. For example, the program “BCLEAN”, which is a component of the “Figaro” software package developed by Keith Shortridge, includes routines that may be used on CCD images to detect and remove bad lines and cosmic ray artifacts from an astronomical image. These routines and modifications of it may be used to detect gamma ray artifacts or hits in an image or a stored representation of an image from a CCD or CMOS imager. Rather than removing them from the image, the routines may be used to identify and characterize gamma rays that strike the imager.

In an embodiment, a variety of pixel intensity ratios may be calculated and used to identify extremely sharp-peaked image features or pixels that may correspond to gamma rays. These pixels may be flagged and evaluated by other tests.

In an embodiment, every pixel in an image may be evaluated based on a set of user or system constants. For example, C(1), C(2), C(3) and C(4) may be user defined constants (although fewer or more constants are also possible). A set of one or more tests to evaluate pixels in an image may include: determining if a pixel data value is greater than zero; determining if a pixel data value is greater than each of the four closest pixels (4CP) in the image; determining if a pixel data value is greater than the average of the 4CP by C(1) counts; determining if a pixel data value is greater than the average of the 4CP by C(2) times that average; determining if a pixel data value is greater than the average of the 4CP by C(3) times the square root of that average; other tests may also be performed. Optionally, a shape parameter may be calculated to assess the general shape of the peak in the image. A ratio may be constructed of [(the central peak value minus the average of the 4CP)/(the average of the 4CP minus the local background average)]. The method may determine if this shape ratio is greater than C(4).

Pixels that pass a number of these tests may be considered to be evidence of a gamma ray. For example, a pixel that has passed the first five tests, and optionally, the sixth may be considered to be a possible gamma-ray detection, and in the flow control of FIG. 13, control would flow to 816. If no pixels pass all tests, the image is deemed to be free of gamma rays; the procedure may then consider the next image 1304.

If gamma rays are detected in an image 1316, the method may be used to determine how many times gamma rays are detected in the next user definable period. The period may be based on a number of frames, which may be from 1 to about 1000 fames or 1 to about 15 frames, or an amount of time, which may be from about 0.5 to about 30 seconds, or from about 1 to about 10 seconds, although shorter and longer times are possible. If user detected gamma rays are present in the user definable period and the threshold is exceeded, for example 3-5 frames, the detection may be considered to be a persistent, bona fide detection, rather than transient noise.

The number of gamma rays detected per image may also be used to determine the veracity of the detection. The user can configure the system to ignore frames having fewer than some threshold number of gamma-ray detections. For example, the threshold may be 1-2 gamma-ray detections per image, but might be set higher in an area with more ambient radiation or at very high altitude. A persistent radioactive source may trigger an alert and control of the system can flow to 1328, but data capture and analysis may continue. All relevant data may be logged and communicated via secure (e.g. encrypted) connection to a monitoring station for further review and possible security operations.

If the activity detected in an image does not repeat, or does not reach the threshold level, the data may be, optionally, logged, and control may be returned to standard data collection acts 1304, 1308, and 1312.

Persistent sources of gamma rays based on pixel or image evaluation may be interpreted as a radiation event, and trigger defined alerts 1324 including operator alarm, computer-based alarm, networked alerts, combinations of these and other alerts. In addition to the alerts, an intensive monitoring mode may be activated for the camera that was responsible for detecting the radiation event 1328. Other cameras, for example nearby cameras, may be put into a faster data taking and analysis mode to improve the chances of detecting a radioactive source. If more than one camera detects radiation, those independent detections may be coordinated 1332.

Intensive monitoring 1328 may have various outcomes including verification that the radioactive source is still near an approximate location, extraction of a more precise location of the radioactive source, and identification of the specific type of radio-isotope.

Once a positive detection or radioactivity is made, subsequent analyses may update the current status, without having to revalidate the alert for persistency. These updates may be used to verify that the source is still present and may be used for the gradient search in section 1328.

Some cameras may be moved by a remote operator, and/or by computer control. These cameras may be panned and tilted to alter their orientation with respect to the radioactive source. As a camera is moved to align its detector more nearly perpendicular to the source, the count rate may increase. Conversely, when the camera is aimed so as to align the detector more edge-wise to the radioactive source, the gamma ray count rate may decrease. In this way, a gradient search may be performed either by the camera operator or by a computer-controlled search (grid, raster, spiral, or other). In one implementation of the gradient search, each time the count rate goes up (averaging over a user-definable number of frames (for example 3-5 frames), a new gradient search may begin with the new maximum-count vector defining the search pattern's new origin. When a global maximum is reached, the detector may either be pointing straight towards, or directly away from the radioactive source. In many cases, the camera's position may make it extremely difficult for a source to be placed in one of these positions (e.g. on the roof of a train station, or floating in mid-air a short distance above a highway). Images of physical objects detected by the imager may be used to help determine and resolve uncertainties in source location. The digital camera data images of physical objects may be used to measure the apparent angular size of identifiable features so as to make estimates of radioactive source strength. For example, if a car is identified as the source of activity, the car's distance from the camera imager may be determined based upon its apparent angular size and its known length, height, etc. using trigonometric relationships. The calculated distance and the known sensitivity may be compared to determine if the data are self-consistent.

The energy deposited by the gamma ray in the detector may be measured in addition to determining the location within the detector and the time of detection. The amount of energy deposited into the detector increases with increasing gamma ray energy. Every radioisotope may have a unique spectrum of gamma-ray energies. Measurement of the energy deposited, plus a comparison to a library of energies may permit determination of the specific radioisotope. That identity may be reported.

Multiple cameras may detect a specific radioactive source. The data from each camera may be analyzed. Each camera may be instructed to carry out an intensive search 1328 to identify the specific isotope and to perform its own gradient search. By combining the image analysis results from each camera, additional information on the source may be obtained. Images from each camera may be used to perform a gradient search. As each camera reports a most probable direction from its gradient search, these vectors may be expected to converge towards a single area. Since the different cameras are positioned in different locations, the resulting triangulation may facilitate source location determination and may help in instances where it is not possible for the data from a single camera to adequately determine a source location. The revised location for the source of radioactivity may be added to the alert information.

The coordination of detector data from various imagers may also permit a re-determination of radioisotope identity by comparing more data to the library values. A higher significance or confidence in gamma rays identified in an image may be obtained by combining analysis results from one or more cameras. The revised estimate of radioactive source properties may be reported via the alert systems.

### Example 4

The laboratory experiments performed with small radioactive sources confirm that imagers based on CCD or CMOS platforms are sensitive to energetic particle impacts. Control experiments verify that the procedures implemented essentially eliminate false-positive alerts from occurring. For such a false alarm to happen, the background rate would have to inexplicably increase by roughly a factor of 20 to 50 and stay that way for seconds. The probability of such an outcome is vanishingly small. Similarly, the detections made in the laboratory experiments resulted in significant detections as shown in FIGS. 6A-6C, even with very low activity sources. The risk of false-negatives (missed sources) is expected to be small for radioactive sources of a size likely to represent a viable threat. Radioactive sources that have a disintegration rate of a few thousand Curies, samples large enough to present a security threat, are expected to be detectable at ranges of at least a few to several hundred meters, and possibly much further, depending upon the degree of shielding, the air-gap attenuation and the inverse-square fall-off.

The effect of geometric foreshortening reducing the projected solid angle of the detector at angles other than perpendicular to the source allow for a gradient search to be executed. This procedure allows for measurements of activity to be made across a range of pan-tilt (or altitude-azimuth) orientations. The comparison of measured levels with pointing direction provides a most probable direction vector that points along the line from the current location of the source through the camera's detector. In many installations, it would be impossible for a radioactive source to be on one of the sides of a camera, reducing the question of location to the range along a vector. This outcome would occur, for example, with a camera mounted high on a pole; the radioactive source could not reasonably be expected to be hanging in mid-air nearby. In other instances, shielding on one or more sides of the camera may be used to attenuate the gamma rays to differentiate radioactive source location. Alternatively or additionally, data from nearby cameras may be used to determine the radioactive material source location.

### Example 5

Radon, a decay product of radium-226 emits an alpha particle and may emit gamma rays (Ra-219) when it decays. Lead, bismuth and thallium decay daughter nuclides of Ra-226 can emit gamma rays and may be used to determine the presence of Radon. For example, the bismuth-214 daughter nuclide of Ra-226 emits gamma rays with main energy peaks of 609 keV, 1,120 keV, and 1,764 keV gamma rays emitted by the radon decay products. A CCD or CMOS imager may be used to detect Radon and its decay products in a variety of settings. The imager may be placed in or near an area to be tested. Optionally, shielding may be used to provide a control. The data from the imager may be analyzed for high energy gamma ray particles to determine the identity and number of counts in the tested area. Alternatively, the capacitor connected to the MOSFET amplifier that converts the signal charge to voltage for the imager may be measured for charge as each pixel is read. A charge or voltage above a given threshold may be used to indicate the presence of gamma rays from a radioactive source in the area being tested.

### Example 6

In one example of an imager detector, the signal generated by the detector is the result of gamma rays impinging upon silicon/silicon dioxide CCDs. A preliminary study of the gamma ray interaction and energy deposition into Si/SiO₂ CCD detectors was undertaken and it was found that these devices were capable of successfully detecting lead-shielded radioisotopes. Models of two different geometries, representing the extremes likely to be found in realistic field operations were studied. One model involved thin slabs of source material, minimizing gamma ray self-absorption; the other model was a spherical distribution that maximizes gamma ray self-absorption. The slab model results supported much higher detection rates, distances and confidence-levels, but even the spherical models result in detectable signals at 20-100 meter distances.

Although the present invention has been described in considerable detail with reference to certain preferred embodiments thereof, other versions are possible. Therefore, the spirit and scope of the appended claims should not be limited to the description and the preferred versions contained within this specification.

What is claimed is:

1. A system comprising:
one or more image detectors, each image detector comprising a pixilated chip designed and configured to detect light to produce images from ambient light;
one or more processors in communication with the one or more image detectors, the processor being capable of detecting pixelated chips having one or more pixels that have interacted with a high energy particle in real time and generating an alert signal identifying at least one of the one or more image detectors having one or more pixels that have interacted with a high energy particle; and
a command center in communication with the one or more processors, the command center being capable of receiving the alert signal from the one or more processors and transmitting a signal to the one or more processors, one or more additional processors, or combinations thereof, said processors being capable of interpreting said signal to at least perform additional analysis on the pixilated image detectors to determine additional interactions with high energy particles.

2. A system comprising:
a first processor and a first processor readable storage medium containing one or more instructions for:
scanning image data from the one or more image detectors, each image detector comprising a pixilated chip designed and configured to detect light to produce images from ambient light,
identifying each pixelated chip having one or more pixels that have interacted with a high energy particle in real time,
generating an alert signal in response to the one or more pixels that have interacted with a high energy particle, and
transmitting the alert signal to a second processor, and
receiving signals from a second processor capable of causing the said first processor. to issue any one of its instructions. to said image detectors.
a second processor in communication with the first processor and second processor readable storage medium containing one or more instructions for:
receiving the signal from the first processor,
generating a signal capable of causing the said first processor to issue any one of its instructions to said image detectors,
transmitting the signal to the first processor and one or more additional processors.
